(19) United States
(12) Patent Application Publication
(10) Pub. No.: US 2020/0066692 A1
(43) Pub. Date: Feb. 27, 2020

(54) PACKAGE DEVICES HAVING A BALL GRID ARRAY WITH SIDE WALL CONTACT PADS

(71) Applicant: INTEL IP CORPORATION, Santa Clara, CA (US)

(72) Inventors: Andreas WOLTER, Regensburg (DE); Bernd WAIDHAS, Pettendorf (DE); Georg SEIDEMANN, Landshut (DE); Klaus REINGRUBER, Langquaid (DE); Thomas WAGNER, Regelsbach (DE)

(73) Assignee: Intel IP Corporation, Santa Clara, CA (US)

(21) Appl. No.: 16/344,633

(22) PCT Filed: Dec. 14, 2016
(86) PCT No.: PCT/US2016/066676

§ 371 Date: Apr. 24, 2019

(51) Int. Cl. H01L 25/10; H01L 23/31; H01L 23/00; H01L 23/498; H01L 21/56; H01L 21/48

(52) U.S. Cl. CPC H01L 25/105; H01L 23/3128; H01L 24/16; H01L 23/49822; H01L 23/49811; H01L 2225/1064; H01L 21/561; H01L 21/4857; H01L 2224/16227; H01L 2924/15331; H01L 23/49816

(57) ABSTRACT

Package devices (systems and methods for their manufacture) may have an integrated circuit (IC) chip mounted on a top surface of a package substrate of and IC package, and embedded in a mold compound formed onto the top surface. They may also have conductive elements mounted on the top surface of the package substrate, embedded in the mold compound, horizontally disposed at a first vertical sidewall of the package device, and having vertical contact pads exposed at the first vertical sidewall. Conductor material traces of the IC package may electrically couple contacts of the chip to the conductive elements. Traces of the IC package may also electrically couple contacts of the chip to bottom surface contacts of the IC package. The vertical contact pads provide a shorter signal path to another device having vertically mounted surface contacts or opposing contact pads, thus improving signaling to the other device.

### BACKGROUND

### Field

Embodiments herein are related in general, to integrated circuit (IC) chip package device interconnection features for improved data signal and other connections (and transmission) from one chip, through a semiconductor packaging device the chip is mounted in, and to another packaging device. The interconnection features may include an array or row of sidewall contact pads on the packaging device for connecting to the other package device.

### Description of Related Art

Integrated circuit (IC) chips (e.g., “chips”, “dies”, “ICs” or “IC chips”), such as microprocessors, coprocessors, graphics processors and other microelectronic devices often use package devices (“packages”) to physically and/or electronically attach the IC chip to a circuit board, such as a motherboard (or motherboard interface), or to another packaging device. The IC chip (e.g., “die”) is typically mounted within a flip chip package or package device that, among other functions, enables electrical connections such as to form a data signal communication channel between the chip and another packaging device, a socket, a motherboard, another chip, or another next-level component (e.g., microelectronic device). Some examples of such package devices are flip chip packages wafer level packages or embedded wafer level ball grid array (eWLB) packages.

There is a desire in the field for an inexpensive and high throughput process for manufacturing such packaging devices. In addition, the process could result in a high package device yield, and an improved data signal communication channel between the chip or package device; and one or more package device(s). In some cases, there is a desire in the field for a package device having better components for providing stable and clean high frequency transmit and receive data signals, or other signal (e.g., power and/or ground) from the chip, through a semiconductor packaging device the chip is mounted in, and to another packaging device (such as having another chip).

### BRIEF DESCRIPTION OF THE DRAWINGS

Embodiments are illustrated by way of example and not by way of limitation in the figures of the accompanying drawings in which like references indicate similar elements. It should be noted that references to “an” or “one” embodiment in this disclosure are not necessarily to the same embodiment, and they mean at least one.

FIG. 1 is a schematic side perspective cross-sectional view of embodiments of an integrated circuit (IC) chip package device including an IC chip mounted on an IC package, where the package device has an array or row of sidewall contact pads formed from metal or conductive material balls for connecting to another package device.

FIGS. 2A-C show schematic side perspective cross-sectional views of embodiments of processes to form and devices resulting from forming multiple integrated circuit (IC) chip package devices that each include an IC chip mounted on an IC package, where each package device has an array or row of sidewall contact pads formed from balls for connecting to another package device.

FIGS. 3A-C show schematic side perspective cross-sectional views of embodiments of processes to form and devices resulting from forming multiple integrated circuit (IC) chip package devices that each include an IC chip mounted on an IC package, where each package device has an array or row of sidewall contact pads formed from wire bonds for connecting to another package device.

FIGS. 4A-C show schematic cross-sectional views of embodiments of a IC chip package device that include IC chips mounted on chip packages and embedded in a mold compound where the package device has an array or row of sidewall contact pads for connecting to another package device, and where the pads include a metal block.

FIG. 5 show a schematic side perspective cross sectional view of embodiments of a IC chip package device that include IC chips mounted on chip packages and embedded in a mold compound where the package device has an array or row of sidewall contact pads for connecting to another package device, and where the package device is an embedded wafer level ball grid array (eWLB) package.

FIG. 6A shows a schematic side perspective cross-sectional view of packages including multiple IC chip package devices having IC chips mounted on substrates and embedded in a mold compound, and having solder applied to their side wall pads.

FIG. 6B shows a schematic side perspective cross-sectional view of packages: (1) including multiple IC chip package devices having IC chips mounted on substrates and embedded in a mold compound; (2) having solder applied to and attaching their opposing side wall pads to each other; and (3) mounted on a printed circuit board (PCB).

FIG. 7A shows a schematic side perspective cross-sectional view of packages including: (1) an IC chip package device having IC chip mounted on a substrate and embedded in a mold compound; (2) having solder applied to and attaching its side wall pads to opposing sidewall pads or traces of a 3-dimensional (3D) molded interconnect device (MID); and (3) mounted onto a horizontal surface of the 3D MID.

FIG. 7B shows a schematic side perspective cross-sectional view of packages including: (1) multiple IC chip package devices, each having an IC chip mounted on a chip package and embedded in a mold compound; (2) each having solder applied to and attaching its side wall pads to opposing sidewall pads or traces of a 3-dimensional (3D) molded interconnect device (MID); and (3) each mounted onto another IC chip package device or onto a horizontal surface of the 3D MID.

FIG. 8 shows a schematic side perspective cross-sectional view of packages including: (1) an IC chip package device having IC chip mounted on a substrate and embedded in a mold compound; (2) side wall pads with opposing spring loaded contact pins of a connector pressed against them; and (3) mounted onto a horizontal surface of a PCB.

FIG. 9 shows a schematic side perspective cross-sectional view of packages including: (1) an IC chip package device having IC chip mounted on a chip package and embedded in a mold compound; (2) horizontally opposing sets of side wall pads with opposing contact tips of flat springs of a connector pressed against them; and (3) mounted onto a horizontal surface of a PCB (and the connector may be mounted onto the PCB as well).

FIG. 10 shows a schematic side perspective cross-sectional view of packages including: (1) an IC chip package device having IC chip mounted on a substrate and embedded in a mold compound and having two opposing beveled sidewalls; (2) horizontally opposing sets of beveled side wall pads with opposing contact tips of flat springs of a connector pressed against them; and (3) mounted onto a horizontal surface of a PCB (and the connector may be mounted onto the PCB as well).

FIG. 11 shows example embodiments of processes to form multiple integrated circuit (IC) chip package devices that each include an IC chip mounted on an IC package, where each package device has an array or row of sidewall contact pads for connecting to another package device.

FIG. 12 shows example embodiments of processes to form multiple integrated circuit (IC) chip package devices that each include an IC chip connected to a redistribution layer of the package, where each package device has an array or row of sidewall contact pads for connecting to another package device, and where the package device is an embedded wafer level ball grid array (eWLB) package.

FIG. 13 illustrates a computing device in accordance with one implementation.

### DETAILED DESCRIPTION

Several embodiments with reference to the appended drawings are now explained. Whenever the shapes, relative positions and other aspects of the parts described in the embodiments are not clearly defined, the scope of embodiments is not limited only to the parts shown, which are meant merely for the purpose of illustration. Also, while numerous details are set forth, it is understood that some embodiments may be practiced without these details. In other instances, well-known circuits, structures, and techniques have not been shown in detail so as not to obscure the understanding of this description.

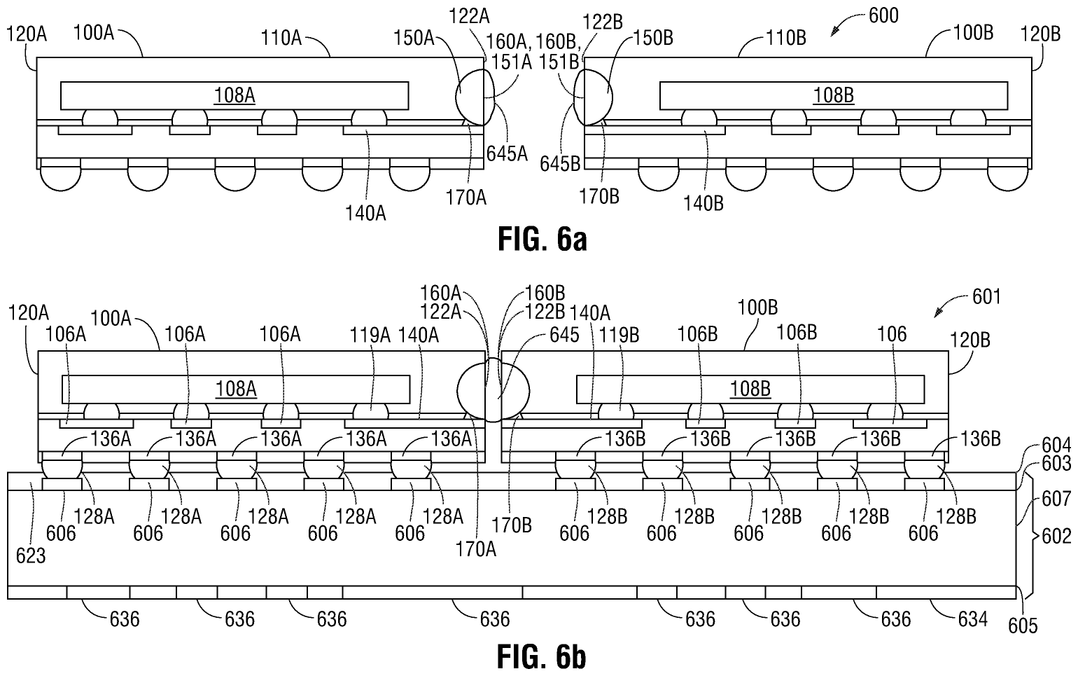

As integrated circuit (IC) chip or die sizes shrink (e.g., see chip 108) and interconnect densities increase, physical and electrical connections require better components for providing stable and clean high frequency transmit and receive data signals between data signal circuitry (e.g., of chip 108) of a chip and data signal transmission surface contacts (e.g., contacts or traces 136 and/or pads 160) to be attached or attached to another package device (e.g., see FIGS. 6-10) (or two physically attached package devices) upon which another IC chip is mounted or is communicating the data signals. In some cases, there is a needed for one or two chips; and the package(s) to have better data transmission interconnect features (e.g., components) for providing stable and clean high frequency transmit and receive data signals through a data signal communication channel between data signal transmit or receive circuits of one chip mounted on a package, through one or more packages, and to data signal receive or transmit circuits of another next-level component (e.g., microelectronic device) or chip attached to the package(s). This may include for providing stable and clean data signals (and optionally power and ground signals) through surface contacts (e.g., contacts or traces 136 and/or pads 160).

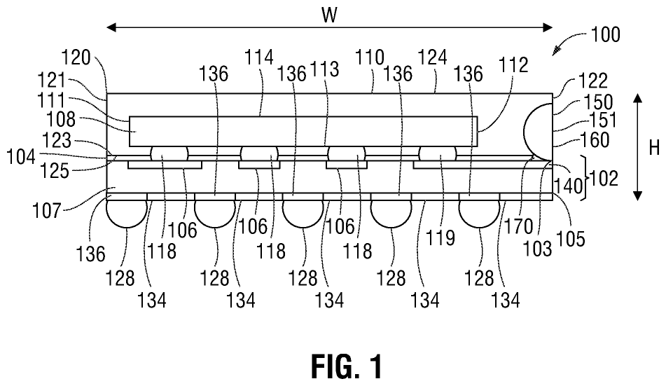

Embodiments herein are related in general, to integrated circuit (IC) chip package device interconnection features for improved data signal and other connections (and transmission) from one chip, through a semiconductor packaging device the chip is mounted in, and to another packaging device, including an array or row of sidewall contact pads on the packaging device for connecting to the other package device. Some embodiments include package to package interconnect features to improve the number and type of connections for data or other signals (e.g., for improved signal connections and transmission), such as from one chip embedded in a package to, through the semiconductor device package the chip is embedded in, and to another electronic device or chip. More particularly, FIGS. 1-12 describe various structures or integrated circuit (IC) chip package devices (e.g., devices 100, 100A, 100B, 300A, 300B, 300C, 400, 500, 800, 900 or 1000; and processes for forming structures thereof) including an IC chip mounted in an IC package, where the package device has an array or row of sidewall contact pads for connecting to another package device. In some cases, such integrated circuit (IC) chip package devices (e.g., devices 100, 100A, 100B, 300A, 300B, 300C, 400, 500, 800, 900 or 1000; and processes for forming structures thereof) may be described as a “package devices having a ball grid array with side wall contact pads” or a “system having package devices having a ball grid array with side wall contact pads” (e.g., devices, systems and processes for forming).

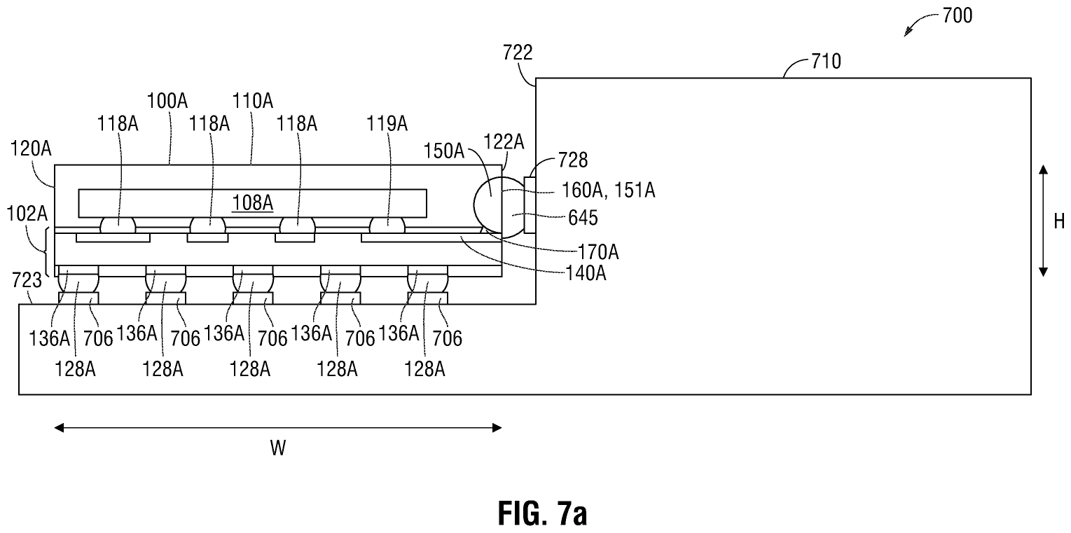

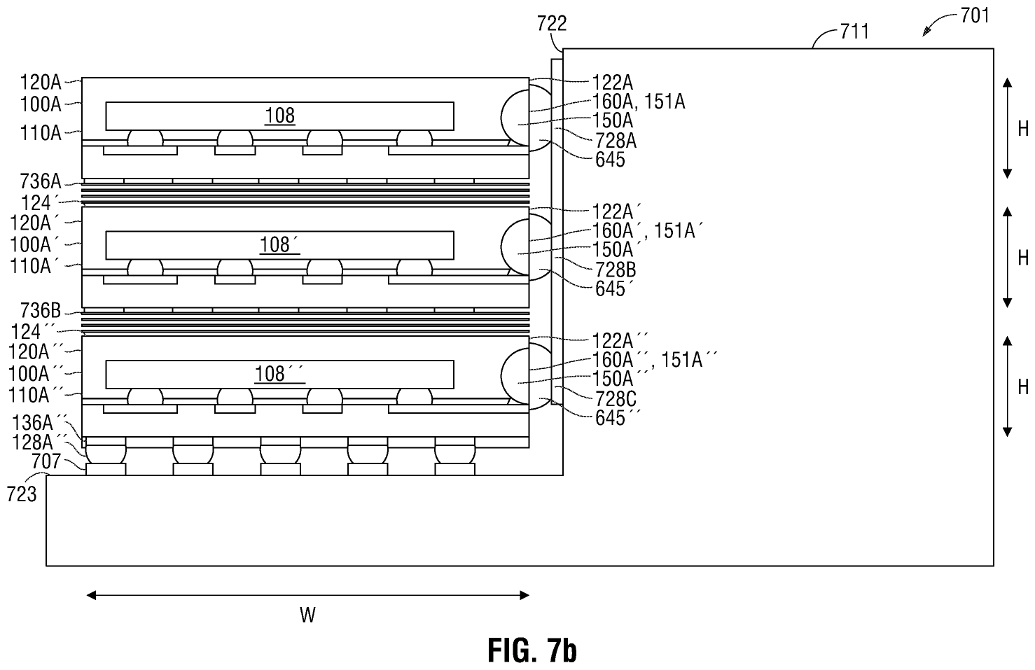

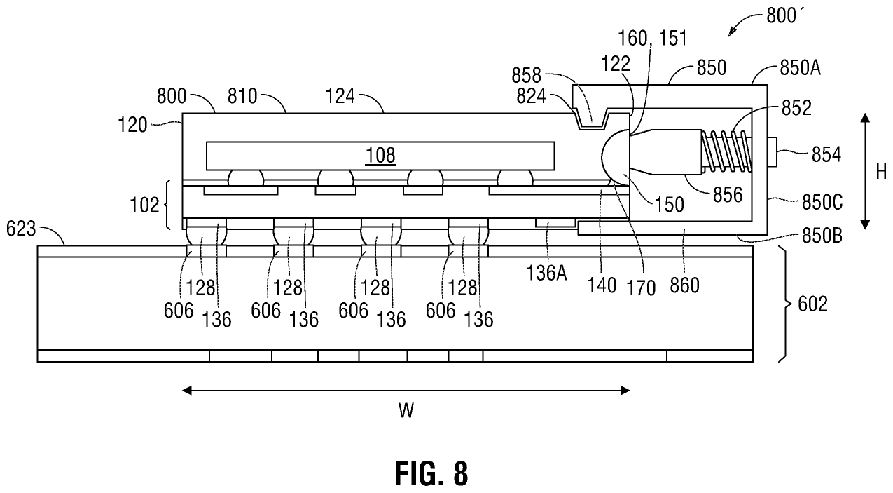

Some embodiments herein may include semiconductor packages providing connections (e.g., solder balls formed on surface contacts) on the bottom of the package for mounting to a printed circuit board (PCB) (e.g., see balls 128 of FIG. 1) or on the topside of the package for a package-on-package mounting (not shown). Some embodiments may also use the package sidewall for electrical interconnects (e.g., see FIGS. 1-10). Some embodiments show a simple and cost efficient method to realize contact pads on the sidewall of a fan-out ball grid array (BGA) package (e.g., see pads 160 and the like of conductive elements 150 and the like described for FIGS. 1-12). In some embodiments, these pads may allow for low parasitic (e.g., parasitic capacitance) lateral connections between neighboring packages on a PCB; or between a package device having such pads and another package device; by connecting through the sidewall contact pads (e.g., see pads 160 and the like of conductive elements 150 and the like of FIGS. 1-10). In some embodiments, this may reduces PCB-complexity and improves electrical performance (e.g., see FIGS. 6 and 8-10). In some embodiments, side wall pads may also be used as second level interconnects to 3-dimensional interconnect devices or PCBs (e.g., see FIGS. 7A-B). Some applications may use such sidewall pads as contact pads for electrical connectors or sockets (e.g., see FIGS. 8-10).

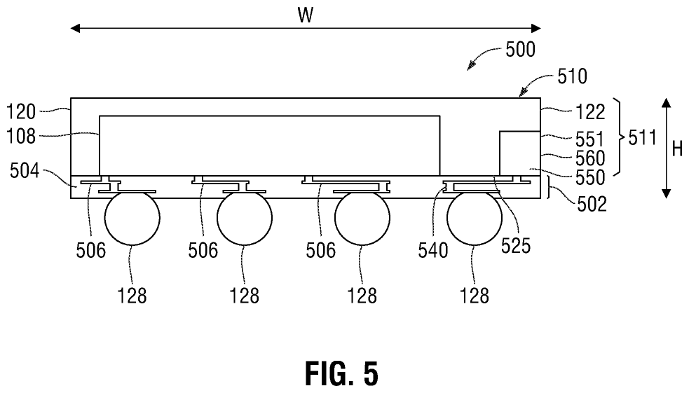

In some embodiments, advanced fan out packages may be assembled in parallel on a substrate or reconstituted wafer (e.g., see FIGS. 1-12). In some embodiments, at the end of the process the packages are singulated. In some cases, being singulated may be or include each package being separated from all of the others formed on a substrate (e.g., a wafer, laminate, “core”, package, package strip, printed circuit board (PCB), or the like) by mechanically dicing or otherwise cutting through the material of the substrate along a path that is disposed between all of the packages that were manufactured on the substrate. In some cases, conductive elements may be mounted side by side with the chips at the position of the later package edge (e.g., see FIGS. 1-10). In some embodiments, they may be electrically connected to a substrate (e.g., see FIGS. 1-4 and 6-10) or redistribution layer stack (e.g., see FIG. 5).

In some embodiments, after over molding dies and conductive elements, the elements may be exposed at the package edge when singulating the packages (e.g., see FIGS. 1-10). In some embodiments, optionally, a surface finish may be applied to the side wall pads (e.g., see FIGS. 6-7). It may ensure solderability, protect against corrosion or allow for good electrical contact (e.g., electrical coupling) by contact springs of a connector (e.g., see FIGS. 8-10).

In some embodiments, such sidewall pads may provide very short connections but wide connections to neighboring packages on the same PCB (e.g., see FIGS. 1-10). The competing path running through the PCB (e.g., to another chip) would be much longer and involve PCB-traces of limited width. The shorter and wider connection by side wall pads of embodiments herein, may translate to lower parasitics and thereby to better electrical performance (e.g., see FIGS. 1-12). As sidewall pads offer an additional path for electrical connections the same overall connectivity (e.g., as compared to a device without sidewall pads) may be realized at lower PCB complexity (e.g., see FIGS. 1-10).

In some embodiments, such sidewall pads may offer a new or an additional option for electronic connections of such a package to another package. In some embodiments, such sidewall pads may offer a new or an additional option for electronic connections of such a package to a PCB (e.g., see FIGS. 6 and 8-10) or to a 3-dimensional interconnect device (e.g., see FIGS. 7A-B). In some embodiments, such sidewall pads may be used to provide reversible connections via contact springs being part of a connector or socket (e.g., see FIGS. 8-10).

In some cases, with the use of the sidewall pads, the electrical interface to the package may not be limited to a horizontally planar arrangement of pads or balls (e.g., not to be limited to balls 128 of FIGS. 1-10). This additional flexibility can be especially important for wearable devices where electrical circuitry has to fit in an optimal way into a given 3-dimensional volume often with a complex shape.

FIG. 1 is a schematic side perspective cross-sectional view of embodiments of an integrated circuit (IC) chip package device including an IC chip mounted in an IC package on a substrate, where the package device has an array or row of sidewall contact pads formed from metal balls for connecting to another package device. FIG. 1 shows a schematic side perspective cross-sectional view of embodiments of IC chip package device 100 having IC chip 108 mounted or within package 110 and being embedded in mold compound 120. Device 100 (e.g., package 110) has an array or row of sidewall conductive elements 150 (e.g., contact pads) for connecting to another package device. In some cases, package 110 includes substrate 102 and mold compound 120; and chip 108 includes bumps 118. In some cases, substrate 102 also includes bumps 118, and chip 108 does not.

In some cases, FIG. 1 shows an embodiment based on flip chip package 110. In some cases, it shows conductive elements 150 located laterally side by side (e.g., in a horizontal plane) with the active chip 108 on substrate 102. In some cases, it shows chip 108 embedded (e.g., with compound 120 over and around sides and the top of the chip) and conductive elements 150 embedded (e.g., with compound over and around one side of the conductive elements) in mold compound 120. In some cases, each of conductive elements 150 are partly exposed, the exposed surface of each forming sidewall pads 160. According to embodiments, having chip 108 and conductive elements 150 embedded in mold compound 120 may include having mold compound 120 formed over and around the outer surfaces of the chip and elements, and onto the top surface of the package.

Package 110 is shown including substrate 102 having laminate 107; traces 106 and 140 formed over a top of laminate 107; solder stop 104 formed over a top of traces 106, traces 140 and laminate 107 that is exposed or horizontally between traces 106 and 140; traces or surface contacts 136 formed over a bottom of laminate 107; solder stop 134 formed over a bottom of laminate 107 that is exposed or horizontally between contacts 136. In some cases, solder stop 134 is also formed over conductors 136 but then opened (e.g., etched) to expose the pads 136 for soldering (e.g., to have solder bumps 128 formed onto pads 136). In some cases, solder stop 134 also extends on parts of the conductor pattern that are not pads for solder connections. It some embodiments, laminate 107 is not exposed (e.g., at surface 105) but is covered by solder stop 134.

In some cases, laminate 107 has top surface 103 having openings or recesses into which (or upon which—not shown) conductor material traces 106 and traces 140 are formed. Traces 106 may physically contact (e.g., touch) or be coupled to other conductor material traces, contacts, or vias within one or more layers of laminate 107, such as to be electrically connected or coupled (e.g., with less than 10 Ohms or with approximately zero electrical resistance) to traces 136. These electrical connections may be for power, ground, and/or data signal transmission.

Traces 140 may extend horizontally along or under surface 103 to contact conductor material solder 170 and/or conductive elements 150. In some cases, traces 140 may physically contact or be electrically coupled to other conductor material traces, contacts, or vias within one or more layers of laminate 107 to contact conductor material solder 170 and/or conductive elements 150. In some cases, traces 140 may electrically couple solder 170 and element 150 to one of bumps 119 or a surface contact of chip 180. In other cases, traces 140 may electrically couple solder 170 and element 150 to one of bumps 128. These electrical connections may be for power, ground, and/or data signal transmission.

In some cases, the material of solder 170 is a solder alloy, some other alloy or pure metal. In some cases, the material of solder 170 is a solder paste, a solder flux, or a solder material as known in the art. The process for generating the solder joint 170 between surface conductor and conductive element 150 may involve solder paste or flux. Both may no longer be present after the joint is formed (e.g., only the solder 170 remains after the process of soldering element 150 to traces 140).

Bumps 118 are disposed through openings in stop 104 (and mold compound 120) and are formed on or physically contact traces 106. Bumps 119 are disposed through openings in stop 104 (and mold compound 120) and are formed on or physically contact traces 140. In some cases, bumps 118 are standard first level interconnect bumps, such as between an IC chip and a package. In some cases, they are small “pillar” shaped bumps. In some cases, the material of bumps 118 and 119 is a solder alloy, some other alloy or pure metal. In some cases, bumps 118 and 119 are metal or conductive material, not paste or flux. In some cases, bumps 118 and 119 are bumps of a conductor material (e.g., they are “conductor material bumps”). In some cases, bumps 118 and 119 are bumps of a conductor material metal or alloy. In some cases, bumps 118 and 119 are copper-pillar bumps or gold stud bumps.

In some cases, laminate 107 also includes bottom surface 105 upon which solder resist or stop 134 is formed. Conductor material traces 136 are formed on bottom surface 105 and covered by solder stop 134 except for the pad openings were the solder balls 128 are applied.

Balls 128 are formed on the bottom surface of surface contacts 136. In some cases, balls 128 are standard second level interconnect balls or bumps, such as between a package and another package or a printed circuit board (PCB). In some cases, they are spherical shaped balls. In some cases, the material of balls 128 is a solder alloy, some other alloy or pure metal. In some cases, the material of balls 128 is a solder material as known in the art to form physical and electrical connections between a package and a PCB. In some cases, balls 128 are balls of a conductor material (e.g., they are “conductor material balls”). In some cases, balls 128 are balls of a conductor material metal or alloy.

In some cases, substrate 102 is a substrate of an IC package or package strip. In some cases, substrate 102 is a substrate of a printed circuit board (PCB). In some cases, substrate 102 is a substrate of a wafer. In some cases, laminate 107 is a “core” of a substrate, a package (or package strip), a printed circuit board (PCB), or a wafer. In some cases, substrate 102 or laminate 107 represents multiple layers or levels of such a PCB.

Chip 108 is shown having left side 111, right side 112, bottom surface 113, and top surface 114. Bumps 118 are formed between (e.g., physically attaching and electrically connecting) some of surface contacts on bottom surface 113 to traces 106. Bumps 119 are formed between (e.g., physically attaching and electrically connecting) other ones of surface contacts on bottom surface 113 to traces 140.

Chip 108, bumps 118 and top surface 123 of solder stop of 104 are shown attached to and encased in (e.g., housed in or packaged in) mold compound 120. Mold compound 120 also encases the left portion 151 of element 150, solder 170 and bumps 119. In some cases, chip 108, is embedded in mold compound 120.

In some cases, chip 108 is an IC chip (e.g., such as microprocessor, coprocessor, graphics processor, memory chip, modem chip, or other microelectronic chip devices) which may be mounted into or have mounted onto it) a package device (e.g., a socket, an interposer, a motherboard, or another next-level component), such as package 110 to form device 100.

In some cases, mold compound 120 is formed of epoxy. In some cases it is epoxy with a dielectric filler. In some cases the filler is silicon dioxide. In some cases it is another dielectric. In some cases, mold compound 120 is a molding compound known to encase a chip or in which a chip is embedded when mounted on a package.

Compound 120 is shown having left side wall 121 right side wall 122 top surface 124 and bottom surface 125. In some cases, chip 108 is housed or encased in package 110 by having compound 120 disposed between (e.g. infused between or existing as a thickness between) side 111 and sidewall 121, side 112 and sidewall 122; top 114 and top 124; and bottom 113 and bottom 125 (except where bumps 118 and 119 exist). Compound 120 may also be disposed between and infused between bottom 113, bumps 118, bumps 119, and surface 123.

Solder 170 and conductive elements 150 are formed through openings in stop 104 and physically attached to and electrically connected to traces 140. In some cases, conductive elements 150 are what remains of spherical shaped metal balls or bumps that have been diced approximately in half at sidewall pads 160. In some cases, left portion 151 of the original bump is shown as elements 150. In some cases, elements 150 are what remains of standard second level interconnect balls, such as between a package and another package or a printed circuit board (PCB). In some cases, they are what remains of were metal balls. Electrical connections through traces 140, elements 150, portions 151, pads 160 and solder 170 may be for power, ground, and/or data signal transmission.

In some cases, conductive elements 150 are metal balls, alloy balls, or metal bumps that were larger than or twice as large as bumps 119 prior to dicing. In some cases they were larger than or twice as large as balls 128 prior to dicing.

In some cases, conductive elements 150 describe a number of metal balls that have been diced to each sidewall pads 160 of a conductor material and shape to be physically attached (permanently or removably) and electrically connected to another sidewall pad, surface contact, connector, or device for communication of signals from chip 108 to another chip or device.

In some cases, elements 150 represents multiple of such elements included in an array or row of sidewall conductive elements 510 (e.g., each having contact pads 160) for connecting to another package device. In some cases, the array or row includes between 2 and 20 of elements 150. In some cases, it includes between 10 and 100.

In some cases, each of elements 150 has a solder 170 physically connecting and electrically connecting each one of elements 150 to a separate one of traces of 140 that is connected to a separate one of bumps 119 that is connected to a separate surface contact of chip 108, such as to communicate a different or separate signal between each of elements 150 and chip 108.

Each of elements 150 may represent a left half 151 (e.g., back half) of a larger metal bump or ball that is diced, when side wall 122 is formed, such as when device 100 is diced from a wafer, a PCB, a strip, or another plurality devices similar to device 100.

In some cases, a top perspective view (e.g., looking down on top 124) shows the width (e.g., into the paper the figure is on) of conductive elements 150 is the same at that of a corresponding one of traces 140 (e.g., the end of trace 140 attached to the element 150).

Device 100 may have width W, height H (excluding balls 128) and a length L going into the page. In some cases, W is between 0.5 and 50 millimeters (mm). In some cases it is between 100 and 500 micrometers (um). In some cases, H is between 0.2 and 3 millimeters (mm). In some cases it is between 50 and 100 um. In some cases it is between 4 and 5 mm. In some cases, L is between 0.5 and 50 mm. In some cases it is between 100 and 500 um.

In some cases, instead of traces 140, different traces extend from (and electrically connects) ones of balls 128, along the bottom of stop 134, to sidewall 122, up sidewall 122 and to corresponding ones of elements 150.

In some cases, package 110 (e.g., substrate 102, elements 150, solder 170 and compound 120) is formed with a standard package plan-of-record (POR).

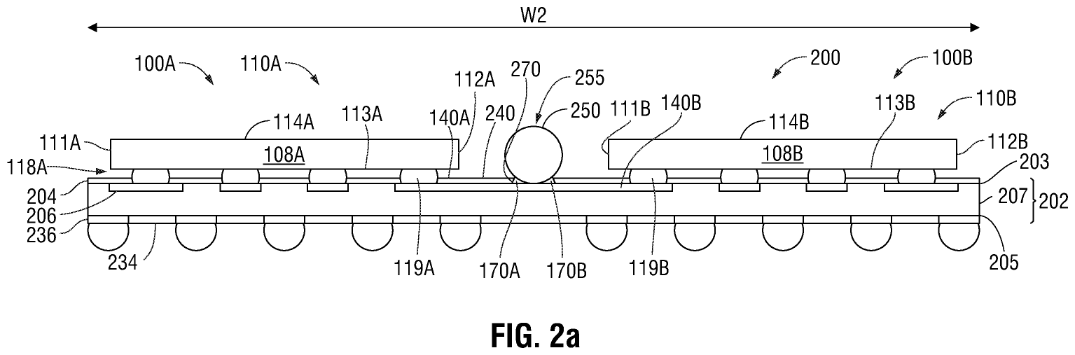

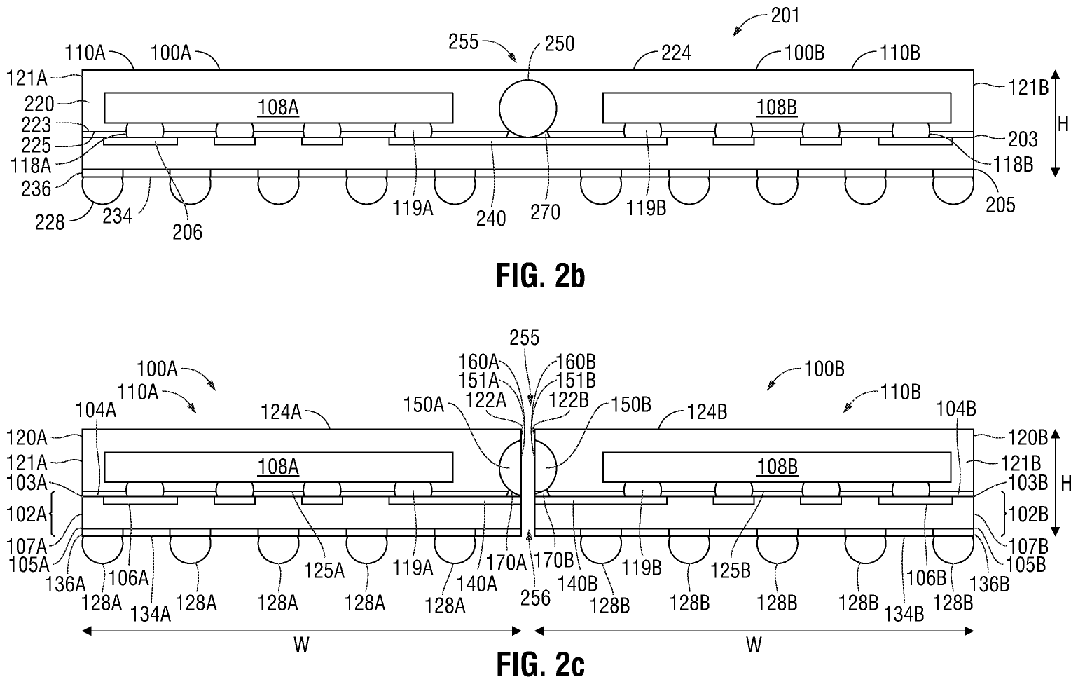

FIGS. 2A-C show schematic side perspective cross-sectional views of embodiments of processes to form and devices resulting from forming multiple integrated circuit (IC) chip package devices that each include an IC chip mounted on an IC package, where each package device has an array or row of sidewall contact pads formed from metal balls for connecting to another package device. In some cases, FIGS. 2A-C show embodiments of processes for producing package device 100 of FIG. 1. In some cases, FIGS. 2A-C show a process for producing flip chip packages 200 or 201 that are produced on strip level, such as using laminate 207 or substrate 202 as the “strip” upon which multiple package devices 200/201, some or all of which can be such as device 100 are formed at the same time (e.g., such as forming the same layer of all of the devices at the same time). There may be between 2 and 1000 devices on such a strip or substrate. In some cases there are between 20 and 200. In some cases, such a strip is a piece of substrate material (e.g., substrate 202) including all the substrates of the individual packages (e.g., packages 110A-B or devices 100A-B) to be produced. In some cases, such a strip is laminate 207 or substrate 202 having multiple package devices, such as device 100 without (e.g., devices 200 of FIG. 2A) or with mold compound 220 (e.g., devices 201 of FIG. 2B) prior to singulation (e.g., devices 100A-B of FIG. 2C).

In some cases, metal ball or elements 250 are soldered side by side between the dies of 2 neighboring packages (e.g., packages 110A-B or devices 100A-B). In some cases, the material of the metal ball or elements 250 are is Cu, gold, an alloy of Cu/Ni/Zn, a solder alloy, a pure metal, or some other alloy.

In some cases, after over molding (e.g., with compound 220 to form devices 201 of FIG. 2B) the packages are singulated (e.g., to form devices 100A-B of FIG. 2C) by cutting between the dies and through the metal balls, such as along pattern 255. In some cases, cutting can be by mechanical dicing or laser. In some cases, as a result of singulating, a part of the metal becomes part of the left package (e.g., solder 170A) and another part becomes part of the right package (e.g., solder 170B). In some cases, as a result of singulating, a part of the conductive element becomes part of the left package (e.g., left portion 151A) and another part becomes part of the right package (e.g., right portion 151B). The cut surface of the metal half spheres along pattern 255 form the side wall pads (e.g., sidewall pads 160A-B).

FIG. 2A shows a schematic side perspective cross-sectional view of packages including multiple IC chip package devices being formed from IC chips which are mounted on chip packages (and are to be embedded in a mold compound). FIG. 2A shows a schematic side perspective cross-sectional view of packages 200 including IC chip package devices 100A-B being formed from (and to have) IC chips 108A and 108B which are mounted on chip packages 110A and 110B, respectively (and are to be embedded in a mold compound).

In some cases, FIG. 2A shows an embodiment of flip chip package devices 200 that include multiple chips mounted on multiple flip chip substrates, such as at least chips 108A-B mounted on at least packages 110A-B. In some cases, FIG. 2A shows flip chip package devices 200 that are produced on strip level, such as using laminate 207 or substrate 202 as the “strip” upon which multiple package devices 200, some or all of which can be such as device 100 are formed at the same time. There may be between 2 and 1000 devices (e.g., such as devices 100A and 100B) on such a strip or substrate. In some cases there are between 20 and 200. In some cases, such a strip is a piece of substrate 202 including all the substrates (e.g., 102A-B) of individual packages 110A-B to be produced. In some cases, such a strip is laminate 207 or substrate 202 having multiple package devices 200 having devices 100A-B without mold compound 220 (e.g., prior to compound 220 of FIG. 2B), and prior to singulation (e.g., of devices 100A-B of FIG. 2C). In some cases, in FIG. 2A, chip 108 is not “encapsulated” or “embedded” within mold compound 120 (e.g., yet, see FIG. 2B), but at least has some of a molding compound (e.g., compound 120) as an under fill between the bottom surface of the chip and top surface 123/125 of the substrate to ensure thermomechanical stability of the package device and/or chip.

In some cases, metal ball or elements 250 are soldered side by side between the dies (e.g., chips 108A-B) of 2 neighboring packages (e.g., packages 110A-B or devices 100A-B). In some cases, the material of the metal ball or elements 250 is copper (e.g., Cu). In some cases it is an alloy of copper, nickel and zinc (e.g., Cu/Ni/Zn). In some cases it is a copper alloy or some other alloy or pure metal.

In some cases, elements 250, 150A and 150B represents multiple of such elements included in an array or row of sidewall conductive elements (e.g., each having contact pads 160A-B) for connecting to another package device. In some cases, the array or row includes between 2 and 20 of the elements. In some cases, it includes between 10 and 100 of the elements.

In some cases, packages 200 (e.g., packages 110A and 110B) include (e.g., are formed from or on) substrate 202. In some cases, packages 110A and 110B both include (e.g., are formed from or on) laminate 207. In some cases, chips 108A-B include bumps 118A-B. In some cases there are additional solder depots on the substrates 102A-B, or on packages 110A-B.

Devices 200 may have width W2, height H (excluding balls 128) and a length L going into the page. In some cases, width W2 is twice (e.g., 2×) width W1.

Packages 110A-B are both shown including substrate 202 having laminate 207; traces 206 and 240 formed over a top of laminate 207; solder stop 204 formed over a top of traces 206, traces 240 and laminate 207 that is exposed or horizontally between traces 206 and 240; traces or surface contacts 236 formed over a bottom of laminate 207; solder stop 234 formed over a bottom of laminate 207 that is exposed or horizontally between contacts 236. In some cases, solder stop 234 is also formed over conductors 236 but then opened (e.g., etched) to expose the pads 236 for soldering (e.g., to have solder bumps formed onto pads 236). In some cases, solder stop 234 also extends on parts of the conductor pattern that are not pads for solder connections. It some embodiments, laminate 207 is not exposed (e.g., at surface 205) but is covered by solder stop 234.

It can be appreciated that IC chip package devices 100A-B can be formed from (and to have) a horizontal portion (e.g., a top perspective area equal to W×L) of substrate 202 and laminate 207; traces 206 and 240; solder stop 204; surface contacts 236; and solder stop 234.

In some cases, laminate 207 has top surface 203 having openings or recesses into which (or upon which—not shown) conductor material traces 206 and traces 240 are formed. Traces 206 may physically contact (e.g., touch) or be coupled to other conductor material traces, contacts, or vias within one or more layers of laminate 207, such as to be electrically connected (e.g., with less than 10 Ohms or zero electrical resistance) to traces 236. These electrical connections may be for power, ground, and/or data signal transmission.

Traces 240 may extend horizontally along or under surface 203 to contact conductor material solder 270 and/or conductive elements 250 (e.g., metal balls). In some cases, traces 240 may physically contact or be coupled to other conductor material traces, contacts, or vias within one or more layers of laminate 207 to contact conductor material solder 270 and/or conductive elements 250. These electrical connections may be for power, ground, and/or data signal transmission.

Bumps 118A-B are disposed through openings in stop 204 and are formed on or physically contact traces 206. Bumps 119A-B are disposed through openings in stop 204 and are formed on or physically contact traces 240. In some cases, bumps 118A-B are standard first level interconnect bumps, such as between an IC chip and a package. In some cases, they are small “pillar” shaped bumps.

In some cases, laminate 207 also includes bottom surface 205 upon which solder resist or stop 234 is formed. Conductor material traces 236 are formed on bottom surface 205 in openings through solder resist or stop 234. In some cases, solder stop 234 also extends on parts of the conductor pattern that are not pads for solder connections. It some embodiments, laminate 207 is not exposed (e.g., at surface 205) but is covered by solder stop 234.

In some cases, substrate 202 is a substrate of an IC package or package strip. In some cases, substrate 202 is a substrate of a printed circuit board (PCB). In some cases, substrate 202 is a substrate of a wafer. In some cases, laminate 207 is a “core” of a substrate, a package (or package strip), a printed circuit board (PCB), or a wafer. In some cases, substrate 202 or laminate 207 represents multiple layers or levels of such a package or PCB.

Chips 108A-B are shown having left sides 111A-B, right sides 112A-B, bottom surfaces 113A-B, and top surfaces 114A-B, respectively. Bumps 118A-B are formed between (e.g., physically attaching and electrically connecting) some of surface contacts on bottom surfaces 113A-B to traces 206. Bumps 119A-B are formed between (e.g., physically attaching and electrically connecting) other ones of surface contacts on bottom surface 213 to traces 240.

In some cases, chips 108A-B are each an IC chip as described for chip 108. They may be the same type of chip. They may be different types of IC chips.

Solder 270 and conductive elements 250 are formed through openings in stop 204 and physically attached to and electrically connected to traces 240. In some cases, conductive elements 250 are spherical shaped bumps or balls that can be diced approximately in half to form opposing sidewall pads. In some cases, each of elements 250 can be diced approximately in half to form left and right portions of the original bump (e.g., see elements 150A-B). In some cases, elements 250 are standard second level interconnect bumps or balls, such as between a package and another package or a printed circuit board (PCB). In some cases, they are spherical shaped balls of conductor material, such as metal.

In some cases, conductive elements 250 are metal balls or bumps that are larger than or twice as large as bumps 119 prior to dicing. In some cases they were larger than or twice as large as balls 128 prior to dicing.

Each of elements 250 may represent a whole (e.g., having two halves) large metal bump or ball to be diced along pattern 255 to form sidewalls of package devices 100A-B that include sidewalls of diced ones of elements 250, such as when devices 100A-B are diced from a wafer PCB, strip, or other plurality devices (such as by dicing substrate 202 or laminate 207).

In some cases, a top perspective view (e.g., looking down on tops 114A-B) shows the width (e.g., into the paper the figure is on) of conductive elements 250 is the same at that of a corresponding one of traces 240 (e.g., the end of traces 140A-B attached to the halves of element 250).

In some cases, each of elements 250 has a solder 170A and B physically connecting and electrically connecting each left and right half of one of elements 250 to a separate one of traces of 140A and B that is connected to a separate one of bumps 119A-B that is connected to a separate surface contact of chips 108A-B, respectively, such as to communicate on a different shaped (e.g., from a top perspective view), routed (e.g., from a top perspective view) or signal one of traces 140A as compared to 140B, between each half of elements 250 and chips 108A-B. In some cases, multiple separate ones of traces of 140A have a different routing through package 110A to chip 108A; as compared to a routing of multiple separate ones of traces of 140B through package 110B to chip 108B. In other cases, the routing of traces 140A and B are the same such as by being symmetrical or a mirror image from a top perspective view. It can be appreciated that physically connecting and electrically connecting each left and right half of one of elements 250 to a separate one of traces of 140A and B of separate packages 100A-B may show a part of a strip 200 to demonstrate the exposure of the side wall pads 160A-B by dicing (e.g., see FIG. 2C). Here, having multiple packages (e.g., packages 100A-B) formed on the same strip 200 allows the advantage of sharing conductive elements 250 between adjacent packages. Thus, in some cases, only one set of elements 25 needs to be fabricated or formed for every two side by side (e.g., to be singulated) package devices. In some cases, there is no electrical connection or functional relation between 119a and b of FIGS. 2A-B as these will be separated anyhow to form devices 100A-B (e.g., see FIG. 2C). In some cases, even if 108a and 108b are the same type of die, traces 119a and 119b may generally correspond to different input/outputs (I/Os).

In some cases, pattern 255 is a lateral package dicing pattern surround each package 110A-B (or device 100A-B) on all of its sides so that they can be singulated. In some cases this is done with a singulation process capable of singulating devices 100A-B and singulating elements 250.

In some cases, surrounding each die on all of its sides with the lateral package dicing pattern (e.g., pattern 255) is “completely separating” each package device (e.g., devices 100A-B) so that a beginning horizontal location of a lateral package dicing pattern separating a package device extends along a horizontal edge of the package device and physically attaches to or touches an ending horizontal location of the same package dicing pattern. Thus, singulating along the dicing pattern necessarily physically separates the package device (e.g., device 100A) from the other package device (e.g., device 100B).

FIG. 2B shows a schematic side perspective cross-sectional view of packages including multiple IC chip package devices being formed from IC chips mounted on chip packages and embedded in a mold compound. FIG. 2B shows a schematic side perspective cross-sectional view of packages 201 including multiple IC chip package devices 100A-B being formed from (and to have) IC chips 108A and 108B which are mounted inside chip packages 110A and 110B (respectively) and embedded in a mold compound 220. It also shows solder balls 228 formed on contacts 236. Here, devices 100A-B have IC chips 108A-B mounted within packages 110A-B and being embedded in mold compound 220. In some cases, in FIG. 2B, chips 108A-B are now “encapsulated” or “embedded” within mold compound 220, such as by at least have compound 220 (1) as an under fill between the bottom surface of the chips and top surface 223/225 of the substrate, and (2) as a side and overfill on the side and top surface of the chips to ensure thermomechanical stability and protection from the elements of the package devices and/or chips.

In some cases, FIG. 2B shows an embodiment of flip chip package devices 201 that include multiple chips mounted inside multiple flip chip packages, such as at least chips 108A-B mounted inside at least packages 110A-B and completely encased in mold compound 220. In some cases, FIG. 2B shows flip chip package devices 201 that are produced on strip level, that have a number of multiple package devices, and where the strip is a piece of substrate 202, such as described for FIG. 2A. In some cases, such a strip is laminate 207 or substrate 202 having multiple package devices 200 having devices 100A-B with mold compound 220 prior to singulation (e.g., of devices 100A-B of FIG. 2C).

In some cases, FIG. 2B may show packages 200 of FIG. 2A having IC chips 108A and 108B which are mounted on chip packages 110A and 110B, respectively, after mold compound 220 has been effused or infused onto (e.g., touching, between or over outer exposed surfaces of) bottoms 113A-B (except where bumps 118A-B and 119A-B exist), bumps 118A-B, bumps 119A-B, and surface 223 (except where bumps 118A-B and 119A-B exist), tops 114A-B, sides 111A-B, sides 112A-B, and elements 250 and solder 170A-B.

Devices 201 may have width W2, height H (excluding balls 128) and a length L going into the page.

In some cases, it shows conductive elements 250 located laterally side by side (e.g., in a horizontal plane) with the active chips 108A-B on substrate 202. In some cases, it shows chips 108A-B and conductive elements 250 embedded in mold compound 220 such that they are not exposed.

Solder balls 228 are formed on the bottom surface of surface contacts 236. In some cases, balls 228 are standard second level interconnect balls, such as between a package and another package or a printed circuit board (PCB). In some cases, they are metal balls or solder balls.

Chips 108A-B, bumps 118A-B and top surface 223 of solder stop of 204 are shown attached to and encased in (e.g., housed in or packaged in) mold compound 220. Mold compound 220 also encases all exposed portions (e.g., left and right) of element 250, solder 270 (e.g., solder 170A-B) and bumps 119A-B. In some cases, chips 108A-B, are embedded in mold compound 220.

In some cases, mold compound 220 is formed of material described for compound 120. Compound 220 is shown having left side wall 121A, right side wall 121B, top surface 224 and bottom surface 225. In some cases, chips 108A-B are housed or encased in packages 110A-B by having compound 220 disposed between (e.g. infused between or existing as a thickness between) sides of the chip and sidewalls of compound as described for chip 108 and package 110. Compound 220 may be infused within package devices 100A-B (except where bumps 118A-B and 119A-B; solder 170 and elements 250 exist). In some cases it may be disposed between and infused between bottom 113A-B, bumps 118A-B, bumps 119A-B, surface 123, solder 170 and elements 250.

FIG. 2C shows a schematic side perspective cross-sectional view of multiple IC chip package devices 100A-B after being singulated, where the package devices include IC chips 108A-B mounted on chip packages 110A-B and embedded in a mold compound 120A-B. In some cases, FIG. 2C may show FIG. 2B after IC chip package devices 100A-B have been singulated along dicing pattern 255 to form trenches 256 along or at pattern 255.

In some cases, FIG. 2C shows an embodiment of flip chip package devices 201 that include multiple chips mounted in multiple flip chip packages, such as at least chips 108A-B mounted in at least packages 110A-B, after singulation of the multiple flip chip packages. In some cases, FIG. 2C shows singulation of each of a number of flip chip package devices 201 that are produced on strip level, such as using laminate 207 or substrate 202 as the “strip”, some or all of which can be such as device 100. In some cases, FIG. 2C shows singulated flip chip package devices that are produced on strip level, that have a number of multiple package devices, and where the strip is a piece of substrate 202, such as described for FIGS. 2A-B. In some cases, such a strip is laminate 207 or substrate 202 having multiple package devices 200 having devices 100A-B with mold compound 220 and after singulation (e.g., of devices 100A-B of FIG. 2C).

In some cases, after over molding (e.g., with compound 220 to form devices 201 of FIG. 2B) the packages of devices 201 are singulated to form devices 100A-B of FIG. 2C by cutting between the dies (e.g., chips 108A-B) and through the metal balls (e.g., elements 250) along pattern 255. In some cases, cutting can be by mechanical dicing or laser. In some cases, as a result of singulating, a part of each of metal balls 250 becomes part of the left package 110A as element 150A, and another part becomes part of the right package 110B as element 150B. In some cases, as a result of singulating, a part of the conductive element becomes portion 151A of the left package 110A and another part becomes portion 151B of the right package 110B. The cut surface of the metal half spheres (e.g., elements 250) along pattern 255 forms a small part of the sidewall of trenches 256, and forms the side wall pads 160A-B.

In some cases, FIG. 2C shows a schematic cross-sectional view of IC chip package devices 100A-B after being singulated along dicing pattern 255, where each package device 100A-B includes or is (1) formed from (and to have) IC chip 108A and 108B which is mounted in chip packages 110A and 110B, respectively, and (2) embedded in a mold compound 220.

In some cases, each of devices 100A-B is a separate device having separate IC chips 108A-B mounted (or within) separate packages 110A-B and separately embedded in mold compound 120.

Devices 100A and 100B (e.g., packages 110A and 100B) may each have an array or row of sidewall conductive elements 150A and 150B (e.g., contact pads) for connecting to another package device. Devices 100A and 100B (e.g., packages 110A and 100B) may each have: (1) a portion of the width or length of substrate 202 (e.g., a strip) as substrate 102A and 102B, respectively; (2) a portion of the width or length of compound 220 as compound 120A and 120B, respectively; and a portion of the width or length of balls 228 as balls 128A and 128B, respectively.

In some cases, FIG. 2C shows embodiments based on flip chip packages 110A-B. In some cases, it shows a portion or half of the width or length of element 250 as conductive elements 150A and 150B located laterally side by side (e.g., in a horizontal plane) with the active chips 108A and 108B on substrate 202 (e.g., as substrates 102A and 102B). In some cases, each of conductive elements 150A and 150B are partly exposed, the exposed surface of each forming sidewall pads 160A and 160B. Elements 150A-B may be described as the left and right portions 151A-B (half or less than half) of element 250, respectively. Packages 110A-B are shown including substrates 102A-B having: (1) a portion of the width or length of laminate 207 as laminates 107A-B; (2) a portion of the width or length of traces 206 as traces 106A-B formed over a top of laminates 107A-B, respectively; (3) a portion of the width or length of stops 204 as solder stops 104A-B formed over a top of traces 106A-B, traces 140A-B and laminates 107A-B that is exposed or horizontally between traces 106A-B and 140A-B, respectively; (4) a portion of the width or length of traces 236 as traces or surface contacts 136A-B formed over a bottom of laminates 107A-B, respectively; and (5) a portion of the width or length of stops 234 as solder stops 134A-B formed over a bottom of laminates 107A-B that is exposed or horizontally between contacts 136A-B, respectively.

In some cases, laminates 107A-B have top surfaces 103A-B having openings or recesses into which (or upon which—not shown) conductor material traces 106A-B and traces 140A-B are formed. These conductor traces can also be formed on the laminate surface 103A-B. Then be are covered by solder resist 104A-B. The solder resist may be opened (e.g., etched) at the position of bumps and balls to expose pads for the formation of a solder joint (e.g., bumps 118 A-B and 119A-B).

In some cases, laminates 107A-B also includes bottom surfaces 105A-B upon which solder resist or stops 134A-B are formed, respectively. Conductor material traces 136A-B are formed on bottom surfaces 105A-B in openings through solder resist or stop 134A-B, respectively. These conductor traces can also be formed on the laminate surface 105A-B. Then be are covered by solder resist 134A-B. The solder resist may be opened (e.g., etched) at the position of bumps and balls to expose pads for the formation of a solder joint (e.g., bumps 128A-B).

Balls 128 are formed on the bottom surface of surface contacts 136. In some cases, balls 128 are standard second level interconnect balls, such as between a package and another package or a printed circuit board (PCB). In some cases, they are balls.

Chips 108A-B, bumps 118A-B and top surfaces 123A-B of solder stops of 104A-B are shown attached to and encased in (e.g., housed in or packaged in) mold compounds 120A-B. Mold compound 120A-B also encases the left portion 151A and right portion 151B of elements 150A-B, solder 170A-B and bumps 119A-B, respectively. In some cases, chips 108A-B, are completely embedded in mold compounds 120A-B.

Compound 120A is shown having left side wall 121A right side wall 122A top surface 124A and bottom surface 125A. Compound 120B is shown having left side wall 122B right side wall 121B, top surface 124B and bottom surface 125B.

In some cases, IC chip package devices 100A-B have been singulated along dicing pattern 255 to form trenches 256 along or at pattern 255 such that: (1) a portion of the width or length of solder 270 is singulated to be solder 270A-B; (2) a portion of the width or length of elements 250 is singulated to be conductive elements 250A-B having sidewall pads 160A-B and halves 151A-B at sidewalls 122A-B, respectively.

In some cases, trenches 256 may represent a pattern of trenches having a lateral (e.g., horizontal) path in the width W and length L directions equal to lateral chip trench pattern 255 (e.g., where trenches 256 has a top perspective view equal to or corresponding to pattern 255). In some cases, trenches 256 may be a pattern of trenches that dice (e.g., separate from each other on all lateral sides) each chip to be diced or desired to be diced from devices 200 or 201. In some cases, trenches 256 may represent a pattern of trenches along pattern 255 that extend at least through height H of devices 201, such as from at least above top surface 224 to at least a bottom surface of stop 234.

In some cases, feature numbers 100A-B, 110A-B, 103A-B, 104A-B, 105A-B, 106A-B, 107A-B, 108A-B, 102A-B, 113A-B, 114A-B, 118A-B, 119A-B, 120A-B, 123A-B, 124A-B, 125A-B, 128A-B, 134A-B, 136A-B, and 140A-B of FIGS. 2A-C may include descriptions for or be the same as (e.g., located the same, formed the same way, of the same material, having the same function) as corresponding feature numbers 100, 110, 103, 104, 105, 106, 107, 108, 102, 113, 114, 118, 119, 120, 123, 124, 125, 128, 134, 136, and 140 of FIG. 1.

In some cases, feature numbers 111A, 112A, 121A, 122A, 150A, 151A, 160A and 170A of FIGS. 2A-C may include descriptions for or be the same as (e.g., located the same, formed the same way, of the same material, having the same function) as corresponding feature numbers 111, 112, 121, 122, 150, 151, 160 and 170 of FIG. 1.

In some cases, feature numbers 111B, 112B, 121B, 122B, 150B, 151B, 160B and 170B of FIGS. 2A-C may include descriptions for or be the same as (e.g., located the same, formed the same way, of the same material, having the same function) as corresponding feature numbers 111, 112, 121, 122, 150, 151, 160 and 170 of FIG. 1, except that they may have opposite left to right lateral (e.g., from the cross-section along width W) directional orientations, as compared to the those corresponding features of FIG. 1.

In some cases, instead of traces 140A-B, different traces extend from (and electrically connects) ones of balls 128A-B, along the bottom of stop 134A-B, to sidewalls 122A-B, up sidewall 122A-B and to corresponding ones of elements 150A-B.

In some cases, packages 110A-B (e.g., substrates 202A-B, elements 150A-B, solders 170 and compound 120A-B) are formed with a standard package plan-of-record (POR).

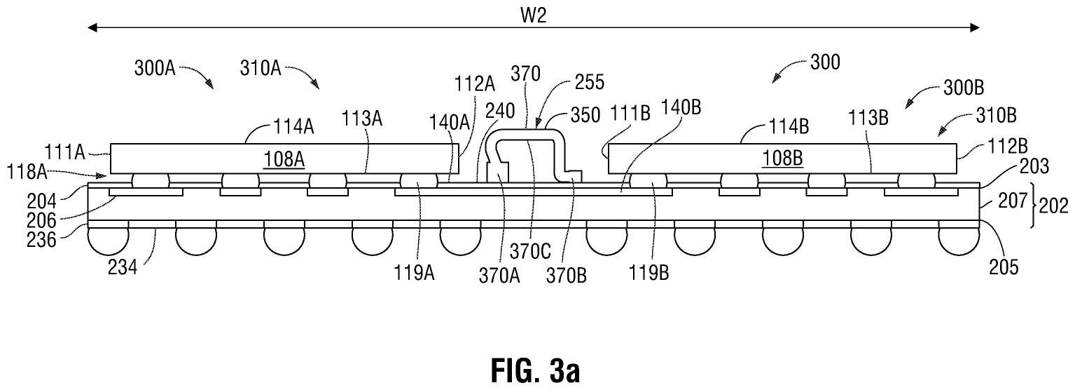

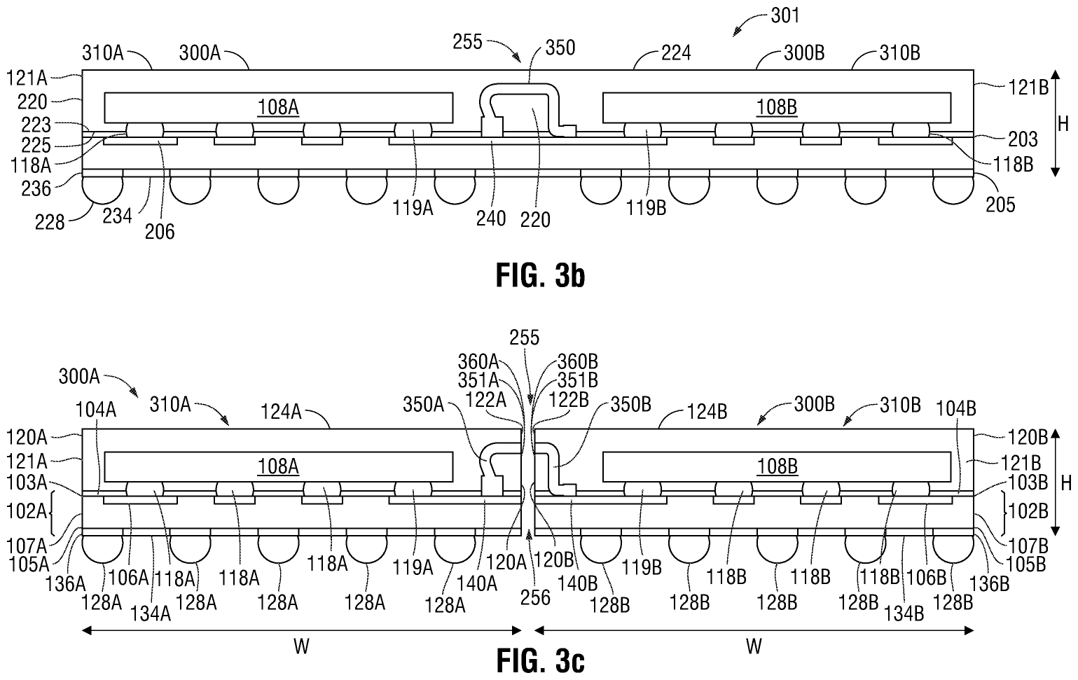

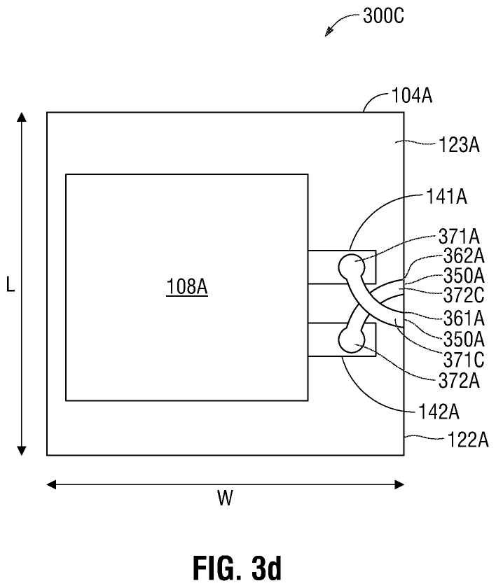

FIGS. 3A-C show schematic side perspective cross-sectional views of embodiments of processes to form and devices resulting from forming multiple integrated circuit (IC) chip package devices that each include an IC chip mounted in an IC package, where each package device has an array or row of sidewall contact pads formed from wire bonds for connecting to another package device. In some cases, FIGS. 3A-C show embodiments of processes for producing package device 300A of FIG. 3C. In some cases, FIGS. 3A-C show a process for producing flip chip packages 300 or 301 that are produced on strip level, such as using laminate 207 or substrate 202 as the “strip” upon which multiple package devices 300/301, some or all of which can be such as device 300A are formed at the same time (e.g., such as forming the same layer of all of the devices at the same time). There may be between 2 and 1000 devices on such a strip or substrate. In some cases there are between 20 and 200. In some cases, such a strip is a piece of substrate material (e.g., substrate 202) including all the substrates of the individual packages (e.g., packages 310A-B or devices 300A-B) to be produced. In some cases, such a strip is laminate 207 or substrate 202 having multiple package devices, such as device 300A without (e.g., devices 300 of FIG. 3A) or with mold compound 220 (e.g., devices 301 of FIG. 3B) prior to singulation (e.g., devices 300A-B of FIG. 3C).

In some cases, wire bonds or elements 350 are formed side by side between the dies of 2 neighboring packages (e.g., packages 310A-B or devices 300A-B). In some cases, the material of the wire bonds or elements 350 is Cu. In some cases it is an alloy, or a pure metal. Common possible materials for elements 350 are Cu, Ag, Au, or Al as main constituents of the wire. In some cases, it is a pure metal having Cu, Ag, Au, or Al as main constituents of the wire. In some cases, it is an alloy including Cu, Ag, Au, or Al as main constituents of the wire.

In some cases, after over molding (e.g., with compound 220 to form devices 301 of FIG. 3B) the packages are singulated (e.g., to form devices 300A-B of FIG. 3C) by cutting between the dies and through the wire bonds, such as along pattern 255. In some cases, cutting can be by mechanical dicing or laser. In some cases, as a result of singulating, a part of the wire bonds becomes part of the left package (e.g., wire bonds 350A) and another part becomes part of the right package (e.g., wire bonds 350B). In some cases, as a result of singulating, a part of the conductive element becomes part of the left package (e.g., left portion 351A) and another part becomes part of the right package (e.g., right portion 351B). The cut surface of the metal half wire bonds along pattern 255 form the side wall pads (e.g., sidewall pads 360A-B).

In some cases, FIGS. 3A-C show a sequence similar to FIGS. 2A-C but with a wire bond (e.g., elements 350) instead of or in place of a metal ball (e.g., elements 250). In some cases, they show an example of ball wedge bond 370A-B with the ball bond 370A on the left and the wedge bond 370B on the right. In some cases, element 350 may be a wire or wire bond, such as having a ball wedge bond with a ball bond 370A on the left and of element 350 and wedge bond 370B on the right end of element 350. Bond 370A may be attached to and electrically coupled to traces 240 or 140A; and bond 370B may be attached to and electrically coupled to traces 240 or 140B.

FIG. 3A shows a schematic side perspective cross-sectional view of packages including multiple IC chip package devices being formed from IC chips which are mounted on chip packages (and are to be embedded in a mold compound). FIG. 3A shows a schematic side perspective cross-sectional view of packages 300 including IC chip package devices 300A-B being formed from (and to have) IC chips 108A and 108B which are mounted on chip packages 310A and 310B, respectively (and are to be embedded in a mold compound).

In some cases, FIG. 3A shows an embodiment of flip chip package devices 300 that include multiple chips mounted on multiple flip chip packages, such as at least chips 108A-B mounted on at least packages 110A-B. In some cases, FIG. 2B shows flip chip package devices 300 that are produced on strip level, that have a number of multiple package devices, and where the strip is a piece of substrate 202, such as described for FIG. 2A. In some cases, such a strip is laminate 207 or substrate 202 having multiple package devices 300 having devices 300A-B without mold compound 220 (e.g., prior to compound 220 of FIG. 3B), and prior to singulation (e.g., of devices 300A-B of FIG. 3C).

In some cases, elements 350 are wire bonds formed side by side between the dies of 2 neighboring packages (e.g., packages 310A-B or devices 300A-B). In some cases, the material of the wire bonds or elements 350 is an alloy or pure metal. In some cases, elements 350 are formed of a foil such as of a pure metal having Cu, Ag, Au, or Al. In some cases it is an alloy foil having Cu, Ag, Au, or Al as main constituents of the wire.

In some cases, elements 350, 350A and 350B represents multiple of such elements included in an array or row of sidewall conductive elements (e.g., each having contact pads 360A-B) for connecting to another package device. In some cases, the array or row includes between 2 and 20 of the elements. In some cases, it includes between 10 and 100.

In some cases, packages 300 (e.g., packages 310A and 310B) include (e.g., are formed from or on) substrate 202 and laminate 207. In some cases, chips 308A-B include or exclude bumps 118A-B.

Devices 300 may have width W2, height H (excluding balls 128) and a length L going into the page.

Packages 310A-B are both shown including substrate 202, laminate 207, traces 206, traces 240, solder stop 204, surface contacts 236, surface 203, surface 205, resist 234, traces 236, bumps 118A-B, and bumps 119A-B as described for FIGS. 2A-C.

It can be appreciated that IC chip package devices 100A-B can be formed from (and to have) a horizontal portion (e.g., a top perspective area equal to W×L) of substrate 202 and laminate 207; traces 206 and 240; solder stop 204; surface contacts 236; and solder stop 234.

Traces 240 may extend horizontally along or under surface 203 to contact bonds 370A-B and/or conductive elements 350 (e.g., wire bonds). In some cases, traces 240 may physically contact or be coupled to other conductor material traces, contacts, or vias within one or more layers of laminate 207 to contact bonds 370A-B and/or conductive elements 350 (e.g., wire bonds). These electrical connections may be for power, ground, and/or data signal transmission.

Chips 108A-B are shown having left sides 111A-B, right sides 112A-B, bottom surfaces 113A-B, and top surfaces 114A-B, respectively. Chips 108A-B are similar to, function similar to, and are attached by bumps 118A-B and bumps 119A-B, as described for FIGS. 2A-C.

Bonds 370 and conductive elements 350 are formed through openings in stop 204 and physically attached to and electrically connected to traces 240. In some cases, conductive elements 350 are wire bonds that can be diced approximately in half (e.g., at the midpoint of middle portions 270C) to form opposing sidewall pads (e.g., 360A-B). In some cases, each of elements 350 can be diced approximately in half to form left and right portions of the original wire bond (e.g., see elements 350A-B). In some cases, elements 350 are standard first level interconnect wire bonds, such as (1) between a conductive trace (or surface contact or contact pad) and another trace (or contact), and/or (2) between a chip and a substrate or lead frame.

In some cases, each of elements 350 has bonds 370A-B physically connecting and electrically connecting each one of elements 350 to a separate one of traces of 240 that is connected to a separate one of bumps 119A-B that is connected to a separate surface contact of chips 108A-B, such as to communicate a different or separate signal between each of elements 350A-B and each of chips 108A-B (e.g., once devices 300A and 300B are singulated from each other; there is no communication between 108A and 108B in FIGS. 3A-B)

Each of elements 350 may represent a whole (e.g., having two halves) wire bond to be diced along pattern 255 to form sidewalls of package devices 100A-B that include sidewalls of diced ones of elements 350, such as when devices 300A-B are diced from a wafer PCB, strip, or other plurality devices (such as by dicing substrate 202 or laminate 207).

In some cases, a top perspective view (e.g., looking down on tops 114A-B) shows the width (e.g., into the paper the figure is on, along length L) of conductive elements 350 is the same at that of a corresponding one of traces 240 (e.g., the end of traces 140A-B attached to the halves of element 350).

Element 350 may be a ball wedge wire bond 350 such as a wire bond having an upside down U-shaped central portion 370C with (e.g., having one end that is) a left ball wedge bond end 370A and with (e.g., having one end that is) a right ball bond 370B. In some cases, element 350 can be described as having central portion 370C extending between, attached to, and electrically coupling bond 370A and 370B.

In some cases, forming element 350 includes forming ball bond 370A, such as a small ball of conductor material on to traces to 240 (or 140A), where central portion 370C is a pillar of conductor material that extends upwards from the ball and includes wedge bond 370B. Then, wedge bond 370B is pressed down onto traces 240 (or 140B) and attached as shown; while being pressed down also bends central portion or pillar section 370C into an upside down U shape as shown.

In some cases, attaching ball bond 370A to traces 240 (or 140A) may include pressing bond 370A onto traces 240 (or 140A) while exposing the bond and trace to a high temperature or high frequency sound (thermal sonic energy) sufficient to bond 370A to the trace while under compression or pressure caused by the pressing.

In some cases, attaching wedge bond 370B to traces 240 (or 140B) may include pressing bond 370B onto traces 240 (or 140B) while exposing the bond and trace to a high temperature or high frequency sound (thermal sonic energy) sufficient to bond or attach bond 370B to the trace while under compression or pressure caused by the pressing.

In some cases, each of elements 350 has a bond 370A and B physically connecting and electrically connecting each left and right half of one of elements 350 to a separate one of traces of 140A and B that is connected to a separate one of bumps 119A-B that is connected to a separate surface contact of chips 108A-B, as described for FIGS. 2A-C.

In some cases, pattern 255 is a lateral package dicing pattern surrounding each package, as described for FIGS. 2A-C.

FIG. 3B shows a schematic side perspective cross-sectional view of packages including multiple IC chip package devices being formed from IC chips mounted on chip packages and embedded in a mold compound. FIG. 3B shows a schematic side perspective cross-sectional view of packages 301 including multiple IC chip package devices 300A-B being formed from (and to have) IC chips 108A and 108B which are mounted on chip packages 310A and 310B (respectively) and embedded in a mold compound 220. It also shows solder balls 228 formed on contacts 236. Here, devices 300A-B have IC chips 108A-B mounted on (or within) packages 310A-B and being embedded in mold compound 220.

In some cases, FIG. 3B shows an embodiment of flip chip package devices 301 that include multiple chips mounted on multiple flip chip packages, such as at least chips 108A-B mounted on at least packages 310A-B and completely encased in mold compound 220. In some cases, FIG. 3B shows flip chip package devices 301 that are produced on strip level, that have a number of multiple package devices, and where the strip is a piece of substrate 202, such as described for FIG. 3A. In some cases, such a strip is laminate 207 or substrate 202 having multiple package devices 300 having devices 300A-B with mold compound 220 prior to singulation (e.g., of devices 300A-B of FIG. 2C).

In some cases, FIG. 3B may show packages 300 of FIG. 3A having IC chips 108A and 108B which are mounted on chip packages 310A and 310B, respectively, after mold compound 220 has been effused or infused onto (e.g., touching, between or over outer exposed surfaces of) bottoms 113A-B (except where bumps 118A-B and 119A-B exist), bumps 118A-B, bumps 119A-B, and surface 223 (except where bumps 118A-B and 119A-B exist), tops 114A-B, sides 111A-B, sides 112A-B, and elements 350.

Devices 301 may have width W2, height H (excluding balls 128) and a length L going into the page.

In some cases, conductive elements 350 are located laterally side by side (e.g., in a horizontal plane) with the active chips 108A-B on substrate 202. In some cases, chips 108A-B and conductive elements 250 are embedded in mold compound 220 such that they are not exposed. In some cases, solder balls 228 are similar to those described for FIGS. 2B-C.

Chips 108A-B, bumps 118A-B and top surface 223 of solder stop of 204 are shown attached to and encased in (e.g., housed in or packaged in) mold compound 220. Mold compound 220 also encases all exposed portions (e.g., left and right) of elements 350 (e.g., parts 350A-B) and bumps 119A-B. In some cases, chips 108A-B, are embedded in mold compound 220.

In some cases, mold compound 220 is formed of material, has sidewalls, has surfaces, and encases chips 108A-B, similar to as described for FIGS. 2B-C. Compound 220 may be infused within package devices 300A-B (except where bumps 118A-B and 119A-B; and elements 350 exist). In some cases it may be disposed between and infused between bottom 113A-B, bumps 118A-B, bumps 119A-B, surface 123, and elements 350.

FIG. 3C shows a schematic side perspective cross-sectional view of multiple IC chip package devices after being singulated, where the package devices include IC chips mounted on chip packages and embedded in a mold compound. In some cases, FIG. 3C may show FIG. 3B after IC chip package devices 300A-B have been singulated along dicing pattern 255 to form trenches 256 along or at pattern 255. In some cases, FIG. 3C shows an embodiment of flip chip package devices 301 that include multiple chips mounted on multiple flip chip packages, such as at least chips 108A-B mounted on at least packages 310A-B, after singulation of the multiple flip chip packages. In some cases, FIG. 3C shows singulation of each of a number of flip chip package devices 301 that are produced on strip level, such as using laminate 207 or substrate 202 as the “strip”, some or all of which can be such as device 100. In some cases, FIG. 3C shows singulated flip chip package devices that are produced on strip level, that have a number of multiple package devices, and where the strip is a piece of substrate 202, such as described for FIGS. 3A-B. In some cases, such a strip is laminate 207 or substrate 202 having multiple package devices 300 having devices 300A-B with mold compound 220 and after singulation (e.g., of devices 300A-B of FIG. 3C).

In some cases, after over molding (e.g., with compound 220 to form devices 301 of FIG. 3B) the packages of devices 301 are singulated to form devices 300A-B of FIG. 3C by cutting between the dies (e.g., chips 108A-B) and through the wire bonds (e.g., elements 350) along pattern 255. In some cases, cutting can be by mechanical dicing or laser. In some cases, as a result of singulating, a part of each of wire bonds 350 becomes part of the left package 310A as wire bonds 350A, and another part becomes part of the right package 310B as wire bonds 350B. In some cases, as a result of singulating, a part of the conductive element becomes portion 351A of the left package 310A and another part becomes portion 351B of the right package 310B. The cut surface of the metal half wire bonds (e.g., elements 350) along pattern 255 forms a small part of the sidewall of trenches 256, and forms the side wall pads 360A-B.

In some cases, FIG. 3C shows a schematic cross-sectional view of IC chip package devices 300A-B after being singulated along dicing pattern 255, where each package device 300A-B includes or is (1) formed from (and to have) IC chip 108A and 108B which is mounted on chip packages 310A and 310B, respectively, and (2) embedded in a mold compound 220. In some cases, each of devices 300A-B is a separate device having separate IC chips 108A-B mounted on (or within) separate packages 310A-B and separately embedded in mold compound 120.

Devices 300A and 300B (e.g., packages 310A and 300B) may each have an array or row of sidewall conductive elements 350A and 350B (e.g., contact pads) for connecting to another package device. Devices 300A and 300B may each have: (1) a portion of the width or length of substrate 202 (e.g., a strip) as substrate 102A and 102B, respectively; (2) a portion of the width or length of compound 220 as compound 120A and 120B, respectively; and a portion of the width or length of bumps 228 as bumps 128A and 128B, respectively.

In some cases, FIG. 3C shows embodiments based on flip chip packages 310A-B. In some cases, it shows a portion or half of the width or length of element 350 as conductive elements 350A and 350B located laterally side by side (e.g., in a horizontal plane) with the active chips 108A and 108B on substrate 202 (e.g., as substrates 102A and 102B). In some cases, each of conductive elements 350A and 350B are partly exposed, the exposed surface of each forming sidewall pads 360A and 360B. Elements 350A-B may be described as the left and right portions 351A-B (half or less than half) of element 350, respectively.

Package devices 300A-B are shown including substrates 102A-B, laminates 107A-B, traces 106A-B, stops 104A-B, traces 140A-B, contacts 136A-B, stops 134A-B, surfaces 103A-B, surfaces 105A-B, stops 134A-B, compounds 120A-B, and balls 128A-B, similar to as described for FIGS. 2B-C.

Chips 108A-B, bumps 118A-B and top surfaces 123A-B of solder stops of 104A-B are shown attached to and encased in (e.g., housed in or packaged in) mold compounds 120A-B. Mold compound 120A-B also encases the left portions 351A and right portions 351B of elements 350A-B and bumps 119A-B, respectively. In some cases, chips 108A-B, are completely embedded in mold compounds 120A-B.

In some cases, after IC chip package devices 300A-B have been singulated along dicing pattern 255 to form trenches 256 along or at pattern 255 such that: (1) a portion of the width or length of section 270C is singulated; or (2) a portion of the width or length of elements 350 is singulated to be conductive elements 350A-B having sidewall pads 360A-B and halves 351A-B at sidewalls 122A-B, respectively.

In some cases, trenches 256 and pattern 255 are similar to and dice devices 300 or 301 similar to as described for devices 200 or 201 of FIGS. 2B-C.

FIG. 3D shows a schematic top perspective cross sectional view of embodiments of a IC chip package device that include IC chips mounted on chip packages and embedded in a mold compound where the package device has an array or row of sidewall contact pads for connecting to another package device, and where the a package device has wire bonds that include crossed connections of wire loops having different height.

In some cases, FIG. 3D shows in top view that the wire bonds 350A-B also allow for crossed connections if wire loops (e.g., 370A-C) are realized with different height in FIGS. 3A-C.

FIG. 3D shows package device 300C including chip 108A mounted on surface 123A of stop 104A such as described mounting chip 108 on surface 123 of stop 104 using bumps 118 and 119, of FIG. 1. It also shows length L and width W of device 300C and sidewall 122A of device 300C.

FIG. 3D shows an embodiment of device 300C with traces 140A including trace 141A and 142A having a first end attached and electrically coupled to separate ones of bumps 119A; and a second end attached and electrically coupled to ball bonds 371A and 372A, respectively, of bonds 370A of elements 350A. Bonds 371A and 372A are attached to, an electrically coupled to middle portions 371C and 372C, respectively, such as to form parts of two of elements 350A.

In some cases, FIG. 3D shows a schematic top perspective cross sectional view of embodiments of a package device 300C which is similar to device 300C, except that adjacent ones of elements 350 include crossed connections of wire loops (e.g., central portions 371C and 372C) having different vertical height (e.g., instead of portions 370C). In some cases, central portions 371C and 372C have different vertical height and end with sidewall pads 361A and 361B at sidewall 122A at different locations along length L than the location of bonds 371A and 372A. In some cases, sidewall pads 361A and 361B end at sidewall 122A at different locations along height H. In some cases they cross over and then curve back up and down to end at the same height at sidewall 122A.

In some cases, FIG. 3D shows portion 372C below or under portion 371C. It can be appreciated that in a different case, portion 372C can be above or over portion 371C. The difference in height between portion 372C and portion 371C may be sufficient to prevent them from touching. In some cases, it may be sufficient so that a sufficient thickness of compound 220 will be infused and disposed between portion 372C and portion 371C to prevent any electrical coupling or contact between them. In some cases, an electrical signal on portion 371C is not in contact with or transmitted to a signal on portion 372C. It can be appreciated that embodiments described with respect to FIG. 3D allow signals to be routed from traces 141A and 142A to different locations along length L at sidewall 122A.

In some cases, feature numbers 141A/142A, 371A/372A, 362A/361A, 372C/371C, of FIG. 3D may include descriptions for or be the same as (e.g., located the same, formed the same way, of the same material, having the same function) as corresponding feature numbers 140A, 370A, 360A, 370C of FIGS. 3A-C, except for they may be part of wire bond versions of elements 350A that have crossed connections of wire loops (e.g., central portions 371C and 372C) having different vertical heights.

In some cases, feature numbers 141A/142A, 371A/372A, 362A/361A, 372C/371C, of FIG. 3D may include descriptions for or be the same as (e.g., located the same, formed the same way, of the same material, having the same function) as corresponding feature numbers 140B, 370B, 360B, 370C of FIGS. 3A-C, except that they may be part of wire bond versions of elements 350A that have crossed connections of wire loops (e.g., central portions 371C and 372C) having different vertical heights; and except that they may have opposite left to right lateral (e.g., from the cross-section along width W) directional orientations, as compared to the those corresponding features of FIGS. 3A-C.

It can be appreciated that processes such as those for embodiments of FIGS. 2A-C or FIGS. 3A-C can be embodiments of processes to form and devices resulting from forming multiple integrated circuit (IC) chip package devices that each include an IC chip mounted on an IC package, where each package device has an array or row of sidewall contact pads of wire bonds that include crossed connections of wire loops having different height, such as device 300C.

In some cases, FIG. 3D uses a process for producing multiple flip chip packages 300C that are produced on strip level, such as using laminate 207 or substrate 202 as the “strip” upon which the multiple package devices are formed as described for forming devices 300A-B or 310A-B.

In some cases, after over molding (e.g., with compound 220 to form devices 300C of FIG. 3D) the packages are singulated (e.g., to form devices 300C) by cutting between the dies and through the wire bonds, such as along pattern 255. In some cases, cutting can be by mechanical dicing or laser. In some cases, as a result of singulating, a part of the wire bonds becomes part of the left package (e.g., wire bonds 350A of FIG. 3D) and another part becomes part of the right package (e.g., wire bonds 350B). In some cases, as a result of singulating, a part of the conductive element becomes part of the left package (e.g., left portion 351A) and another part becomes part of the right package (e.g., right portion 351B). The cut surface of the metal half wire bonds, along pattern 255, form the right side wall pads of the left package (e.g., sidewall pads 361A and 362A of device 300C) and the corresponding left sidewall pads for the right package.

In some cases, instead of traces 140A-B, different traces extend from (and electrically connect) ones of balls 128A-B, along the bottom surface 105A-B of laminate 107-B, to sidewalls 122A-B, up sidewall 122A-B and to corresponding ones of elements 350A-B. Such bottom traces may be on the laminate surface or embedded in the laminate so that the surface of those trades is exposed. Generally, such traces may be covered with solder resist 134A-B; the resist having openings to define pads (e.g., pads 136A-B) for the formation of solder joints.

In some cases, packages 310A-B (e.g., substrates 202A-B, elements 350A-B and compound 120A-B) are formed with a standard package plan-of-record (POR).

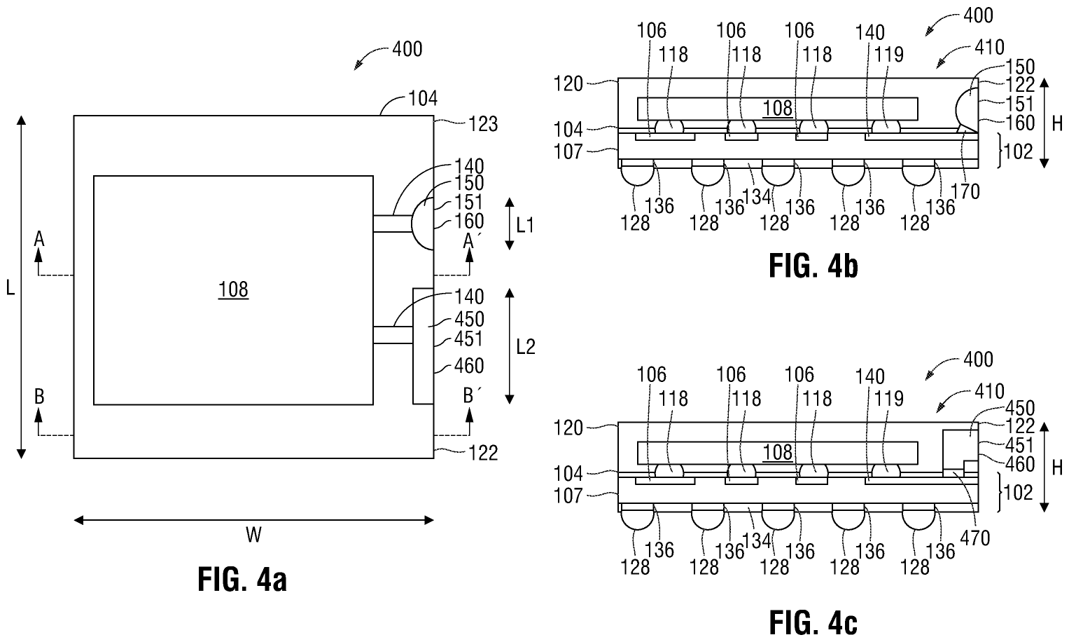

FIGS. 4A-C show schematic cross-sectional views of embodiments of a IC chip package device that include IC chips mounted on chip packages and embedded in a mold compound where the package device has an array or row of sidewall contact pads for connecting to another package device, and where the pads include a metal block.

FIG. 4A shows a top view of embodiments of IC chip package device 400 that include IC chip 108 mounted on chip package 410 and embedded in a mold compound 120 where the package device has an array or row of sidewall contact pads 160 and 460 for connecting to another package device, and where the pads include a metal block (e.g., element 450). FIGS. 4B-C show schematic side perspective cross sectional view through perspectives A-A′ and B-B′ respectively of FIG. 4A.

In some case, the contact pads of device 400 are for a portion of a metal ball (element 150 from element 250) in FIG. 4B, and besides the metal ball portion is also a metal block portion (element 450) in FIG. 4C which can be used to realize a larger sidewall pad 460 extending along the package edge (e.g., along length L). In some cases, element 450 is a metal part that is a stamped part as known in the art. In some cases, element 450 is a metal part that is generated by 3-dimensional printing as known in the art. In some cases, instead of a full metal part, element 450 is metal embedded in a polymer part or deposited on the surface of a polymer part as for example in the case of a molded interconnect device (MID) as known in the art. In some cases, element 450 is a material (e.g., insulator) other than polymer with metal deposited on its surfaces, including at sidewall 122 to form pad 451.

In some cases, because element 450 is a wider element (e.g., along length L), it provides the benefits of increased (e.g., as compared to elements 150 and 350 or 351A) electrical signal coupling (including at least for ground or direct current DC power signals) and thermal coupling. In some cases, because element 450 is a wider element, it provides the benefits of being easier to match to a mechanical connection (e.g., see at least FIGS. 8-10).

In some cases, elements 150 and 450 represents multiple of such elements included in an array or row of sidewall conductive elements (e.g., each having contact pads 160 and 460) for connecting to another package device. In some cases, the array or row includes between 2 and 20 of the elements. In some cases, it includes between 10 and 100.

FIGS. 4A-C show package device 400 including chip 108 mounted on surface 123 of stop 104, such as using bumps 118 and 119 (e.g., see FIG. 1). They also shows length L, height H, and width W of device 400 and sidewall 122 of device 400. In some cases, FIG. 4B shows a schematic side perspective cross sectional view similar to that of FIG. 1. Device 400 may have traces 140 and 140 having a first end attached and electrically coupled to separate ones of bumps 119; and a second end attached and electrically coupled to element 150 and conductive element, respectively. In some cases, elements 450 may be described as metal blocks, such as blocks of conductor material. In some cases they may be a material covered with conductor material.

In some cases, element 150 represents multiple of such elements included in an array or row of sidewall conductive elements 150 (e.g., contact pads) for connecting to another package device. In some cases, element 450 represents multiple of such elements included in an array or row of sidewall conductive elements 450 (e.g., contact pads) for connecting to another package device. In some cases, the array or row includes more than one of elements 150 and more than one of elements 450. In some cases, the array or row includes between 2 and 20 of elements 150 and between 2 and 20 of elements 450.

In some cases, each of elements 450 has a solder 470 physically connecting and electrically connecting each one of elements 450 to a separate one of traces of 140 that is connected to a separate one of bumps 119 that is connected to a separate surface contact of chip 108, such as to communicate a different or separate signal between each of elements 450 and chip 108. Solder 470 may be a solder such as described for solder 170. In some cases, the shape of the element 450 is chosen to avoid exposed solder 470 after dicing. This way solder 470 cannot flow off of the package device when soldering the package device to another package device or PCB after singulation. The metals used for trace 140 and element 470 may not be suitable for directly attaching to element 450, thus a solder material may be used here.

In other cases, solder 470 does not exist or is excluded. In this case, each of elements 450 is directly physically connected and electrically connected to a separate one of traces of 140 that is connected to a separate one of bumps 119 that is connected to a separate surface contact of chip 108, such as to communicate a different or separate signal between each of elements 450 and chip 108.

In some cases, FIGS. 4A-C show schematic views of embodiments of a package device 400 which is similar to device 100, except that it also includes elements 450. In some cases, sidewall pads 460 (e.g., and elements 450) at sidewall 122 have longer length L2 along length L than the length L1 of pads 160 (e.g., and elements 150). In some cases, the length L2 is twice or three times length L1. Sometimes it is between 1.5 and 4 times longer. In some cases, pads 460 may have the same height (e.g. along H1) as pads 160. In some cases they may have a greater height than pads 160. In some cases this greater height may be 1.5 to 2 times greater.

In some cases, feature numbers 450, 451, 460 and 470, of FIG. 4A-C may include descriptions for or be the same as (e.g., located the same, formed the same way, of the same material, having the same function) as corresponding feature numbers 150, 151, 160 and 170 of FIG. 1, except for that they may have longer length L2 along length L than the length L1 those of FIG. 1.

In some cases, feature numbers 450, 451, 460 and 470, of FIG. 4A-C may include descriptions for or be the same as (e.g., located the same, formed the same way, of the same material, having the same function) as corresponding feature numbers 150, 151, 160 and 170 of FIG. 1, except for that instead of having a round or spherical (e.g., ball) shape they may have a square or rectangular shape from above and from the side view. In some cases, they may have a rectangular shape from above and a square shape from the side view. In some cases, they may have a cube shape, or a cuboid shape (e.g., as a 3-dimensional shape).

It can be appreciated that processes such as those for embodiments of FIGS. 2A-C or FIGS. 3A-C can be embodiments of processes to form and devices resulting from forming device 400.

In some cases, FIGS. 4A-C uses a process for producing multiple flip chip packages 400 that are produced on strip level, such as using laminate 207 or substrate 202 as the “strip” upon which the multiple package devices are formed as described for forming devices 300A-B or 310A-B.

In some cases, after over molding (e.g., with compound 220 to form devices 400 of FIGS. 4A-C) the packages are singulated (e.g., to form devices 400) by cutting between the dies and through the metal balls and metal blocks, such as along pattern 255. In some cases, cutting can be by mechanical dicing or laser. In some cases, as a result of singulating, a part of the metal balls and metal blocks becomes part of the left package (e.g., elements 150 and 450 of FIGS. 4A-C) and another part becomes part of the right package. In some cases, as a result of singulating, a part of the conductive elements 150 and 450 become part of the left package (e.g., left portions 151 and 451) and another part becomes part of the right package. The cut surface of the metal half metal balls and metal blocks along pattern 255 form the right side wall pads of the left package (e.g., sidewall pads 160 and 460 of device 400) and the corresponding left sidewall pads for the right package.

In some cases, instead of traces 140, different traces extend from (and electrically connects) ones of balls 128, along the bottom surface 105A-B of laminate 107-B, to sidewall 122, up sidewall 122 and to corresponding ones of elements 150 and 450. Such bottom traces may be on the laminate surface or embedded in the laminate so that the surface of those trades is exposed. Generally, such traces may be covered with solder resist 134A-B; the resist having openings to define pads (e.g., pads 136A-B) for the formation of solder joints.

In some cases, some of traces 140 may electrically couple solder 470 and element 450 to make contact to a contact of another electronic device (e.g., other than a PCB upon which device 400 is mounted, such as another devices shown as device 100B, 710, 711, 850, or 950). In some cases, one of these electrical connections may be for ground (e.g., transmitted by a first side contact 450 or 150) that is required as reference for a data signal that is transmitted via a second one of these electrical connections (e.g., transmitted by a second side contact 150 or 450).

Some of traces 140 may extend horizontally along or under surface 103 to contact conductor material solder 470 and/or conductive elements 450. In some cases, some of traces 140 may physically contact or be coupled to other conductor material traces, contacts, or vias within one or more layers of laminate 107 to contact conductor material solder 470 and/or conductive elements 450. In some cases, some of traces 140 may electrically couple solder 470 and element 450 to one of bumps 119 or a surface contact of chip 180. In some cases, some of traces 140 may electrically couple solder 470 and element 450 to one of balls 128. These electrical connections may be for power, ground, and/or data signal transmission.

In some cases, package 410 (e.g., substrate 102; elements 150 and 450; solder 170 and 470; and compound 120) is formed with a standard package plan-of-record (POR).

FIG. 5 show a schematic side perspective cross sectional view of embodiments of a IC chip package device that include IC chips mounted on chip packages and embedded in a mold compound where the package device has an array or row of sidewall contact pads for connecting to another package device, and where the package device is an embedded wafer level ball grid array (eWLB) package. In some cases, FIG. 5 shows a side view of a package device 500 that is an embedded wafer level ball grid array (eWLB) package 510 and chip 508 and conductor material (e.g., conductive) elements 550 embedded in molding compound 120. It is considered that eWLB package device 500 may include chip 108 and in this case also a conductive element 550.

In some cases, device 500 is an IC chip package device including: (1) package portion 511 (of chip package 510) having IC chip 108 and elements 550 and embedded in a mold compound 120; and (2) redistribution layers (RDL) stack portion 502 on surface 525 of portion 511. In some cases, device 500 has an array or row of sidewall contact pads 560 for connecting to another package device.

In some cases, FIG. 5 shows embodiments based on (e.g., where the package device 500 includes) eWLB package 510 instead of flip chip packages 110, 110A, 110B, 310A, 310B or 410 such as shown in FIGS. 1-4. However, it is considered that elements 550 may represent or be any of elements 150, 150A, 150B, 350A, 350B or 450 such as shown in FIGS. 1-4, but where the element has redistribution layers (RDL) stack 502 formed directly on exposed surface 525 of elements 550. In some cases, elements 550 provide all of the advantages of any of elements 150, 150A, 150B, or 450. In this eWLB technology the RDL may be applied after embedding the die in mold compound.

In some cases, elements 550 represents multiple of such elements included in an array or row of sidewall conductive elements 550 (e.g., each having contact pads 560) for connecting to another package device. In some cases, the array or row includes between 2 and 20 of elements 550. In some cases, it includes between 10 and 100.

In some cases, package device 500 may including chip 108 physically attached and electrically coupled to traces 506 (and optionally also to traces 540). Device 500 may also have length L, height H, and width W; and sidewall 122. In some embodiments, the eWLB device 500 may not use solder bumps as first level interconnects, but may have chip 108 embedded in mold compound 120, then the RDL may be formed on the die “bottom” surface and the surrounding mold surface 525. RDL formation may also include formation of vias to the chip pads and/or contacts.

In some cases, each of elements 550 is directly physically connected and electrically coupled to a separate one of traces of 540 that is connected to a separate one of signal surface contacts of chip 108, such as to communicate a different or separate signal between each of elements 550 and bumps 128 or chip 108.

Traces 506 and 540 may be a conductive or conductor material (e.g., metal or alloy) such as described for traces 106, 134, 136 or 140. Dielectric 204 may be a non-conductive material or stop (e.g., oxide, polyimide, PBO (Polybenzoxazole)) such as described for stop 104, stop 134 or laminate 107.

In some cases, sidewall pads 560 (e.g., and elements 550) at sidewall 122 have the same length L1 as pads 160 (e.g., and elements 150). In some cases, pads 560 may have the same height (e.g. along H1) as pads 160.

In some cases, feature numbers 550, 551, 560 and 570, of FIG. 5 may include descriptions for or be the same as (e.g., located the same, formed the same way, of the same material, having the same function) as corresponding feature numbers 150, 151, 160 and 170 of FIG. 1, except for that instead of having a round or spherical (e.g., ball) shape they may have a square or rectangular shape from above and from the side view; and except for that they have traces 540 and dielectrics 504 formed directly on their surface 525. In some cases, they may have a rectangular shape from above and a square shape from the side view.

In some cases, forming device 500 includes having chip 108 (e.g., the “die”) and conductive elements 550 embedded in mold compound 120 so that their front side (e.g., surface 525) is exposed (e.g., before forming stack 502). Then the RDL-stack 502 is generated on (e.g., formed physically directly onto and touching) this exposed front side surface 525. Finally balls 128 can be applied to the packages 510 (e.g., to traces 506 and 540; or to device 500). Then the packages 510 (or device 500) can be singulated.

In some cases, multiple ones of devices 500 are formed. In some cases, this includes having multiple chips 108 and elements 550 infused with (or embedded in) compound 120 to form package portions 511 having exposed surface 525 of chips 108, compound 120, and elements 550, prior to forming stack 502 (e.g., dielectrics 504 and traces 506 on surface 525) and balls 128 (e.g., on traces 506 and 540).

In some cases, multiple ones of portions 511 may be formed on a metal carrier with a special foil coated with adhesive on both sides, such as by forming temporary heat activated adhesives on the foil; then placing chips 108 and elements 550 on the foil; and then infusing molding compound 120 onto the foil to embed chips 108 and elements 550 on the foil/metal carrier. In some cases, the adhesive is between (all of compound 120, chips 108 and elements 550) and the foil. In some cases the carrier is made of a metal. In some cases it is a plastic or polymer. In some cases, the foil is laminated onto the carrier (e.g., a wafer), using a lamination tool; then the chips 108 are placed onto the foil using a chip placement (e.g., a pick and place) tool; and then the compound 120 is molded onto and over the chips 108 and elements 550 by mold pressing using a mold press tool. In some cases, the carrier is a wafer (e.g., metal or silicon) is a strip such as described for packages 200. In some cases, such forming on a foil or carrier, may form multiple packages 510 or package devices 500 at once, that will later be diced, similar to forming devices 100A-B on a “strip”.

In some cases, portions 511 are then debonded from the carrier by adding heat to unbond the adhesive, thus, leaving surface 525 exposed. In some cases, the debonding is performed by a debonding tool.

Once portions 511 are debonded, they may be inverted, and stack 502 may be formed on surface 525. In some cases, this begins when debonded portions 511 (e.g., as a strip or from the foil) are inverted as compared to how portion 511 is vertically shown in FIG. 5.

After debonding and inverting portions 511, dielectrics 504, traces 506 and traces 540 can be formed onto surface 525. Dielectrics 504, traces 506 and traces 540 can be formed onto surface 525 in layers. In some cases they can be formed as is known for forming IC packages. In some cases, each of traces 506 is physically attached and electrically coupled to one or more of signal contacts of chip 108 (e.g., without solder balls, such as by forming the metal of traces 506 directly onto the metal of the signal contacts of chip 108).

After forming stack 502, balls 128 can be formed onto traces 506 and 540 (or surface contacts attached to those traces).

In some cases, dielectrics 504, traces 506 and traces 540 can be formed onto surface 525 by: applying a first layer of dielectric over surface 525; then forming openings (e.g., etching with a mask) in the first layer of dielectric to surface contacts or areas of chips 108 and elements 550; then, depositing a seed layer over the first layer of dielectric and into the openings; then, forming and etching a layer of plating resist to form openings for plating a first layer of traces 506 and 540 onto the seed layer; then, plating a first layer of traces 506 and 540 in the openings in the resist and onto the seed layer; then stripping the resist and etching the seed layer off of the dielectric where the plating of a first layer of traces 506 and 540 does not exist. Then, applying a first layer of dielectrics 504 through stripping the resist and etching the seed layer to form first layer of traces 506 and 540 can be repeated as desired to form multiple levels of dielectrics 504 and multiple levels of various patterns of traces 506 and 540 as desired. Then a solder resist/stop can be formed (e.g., as a final exposed layer of dielectrics 504) over the top and exposed layer of plating and dielectric. Then the solder stop can be etched to form openings to surface contacts of the exposed plating (of the traces 506 and 540). Then, solder balls can be formed in the openings and onto the surface contacts (of the traces 506 and 540).

In some cases, numerous (e.g., between 2 and 20; or between 20 and 200) of portions 511 are formed on the same mold wafer or mold panel. In some cases, the number is as described for forming devices 100A-B of FIGS. 2A-C.

In some cases, after forming 502 or balls 128, devices 500 can be singulated from each other. In some cases, this singulation will be similar to described above for FIGS. 2-4. In some cases, elements 550 may be half of a larger cuboid square or rectangular element such that elements 550 has left half 551 and there is a right half of a larger element that was diced in half when device 500 was singulated from a right side neighbor (e.g., see FIGS. 2 A-C).

In some cases, traces 540 are physically attached to and electrically coupled to a single contact of chip 108. In some cases, they are physically attached to and electrically coupled to both, a single contractive chip 108 and one solder ball 128 (e.g., as shown).

In some cases, stacked 502 (e.g., an electrics 504, traces 506 and traces 540) are formed according to a standard packaging processing or plan of record (POR). Singulating devices 500 exposes sidewall 122, pad 560, and separates each of devices 500 from all other devices 500 that were formed from portions 511 that began by being formed on the carrier (and then were debonded from the carrier prior to forming stack 502).

It can be appreciated that processes such as those for embodiments of FIGS. 2A-C, FIGS. 3A-C or FIG. 4 can be embodiments of processes to form and devices resulting from forming device 500. In some cases, FIG. 5 uses a process for producing multiple flip chip packages 500 that are produced on strip level, such as using portions 511 as the “strip” upon which the multiple package devices are formed as described for forming devices 300A-B or 310A-B.

In some cases, after forming portions 511 and 502, and optionally balls 128 of FIG. 5, the strip of devices 500 are singulated (e.g., to form devices 500) by cutting between the dies and through elements 550, such as along pattern 255. In some cases, cutting can be by mechanical dicing or laser. In some cases, as a result of singulating, a part of elements 550 becomes part of the left package (e.g., elements 550 of FIG. 5) and another part becomes part of the right package. In some cases, as a result of singulating, a part of the conductive elements 550 become part of the left package (e.g., left portions 551) and another part becomes part of the right package. The cut surface of the half elements 550 along pattern 255 form the right side wall pads of the left package (e.g., sidewall pads 560 of device 500) and the corresponding left sidewall pads for the right package.

In some cases, package 510 (e.g., stack 502, elements 550 and compound 120) is formed with a standard package plan-of-record (POR).

Can be appreciated that embodiments described for FIGS. 1-5 allow different families of chip or die packages (e.g., devices 100, 100A, 100B, 300A, 300B, 300C, 400 or 500) that began by being formed on a single strip or carrier (e.g., by the processes described herein). After forming the different families, each of the package devices can be singulated from every other one that began by being formed on the strip or carrier.

In some cases, FIGS. 1, 2A-C, 3A-C, 3D, 4 and 5 describe various structures or package devices (e.g., devices 100, 200, 100A, 100B, 300, 301, 300A, 300B, 300C, 400 or 500) for forming or having sidewall conductive elements or contact pads for side-by-side connecting one package having an IC chip to another package.

In some cases, FIGS. 2A-C, 3A-C, 3D, 4 and 5 describe various processes for forming such structures or package devices (e.g., devices 100, 200, 100A, 100B, 300, 301, 300A, 300B, 300C, 400 or 500) having sidewall conductive elements or contact pads for side-by-side connecting one package having an IC chip to another package.

FIG. 6A shows a schematic side perspective cross-sectional view of packages including multiple IC chip package devices having IC chips mounted on chip packages and embedded in a mold compound, and having solder applied to their side wall pads. FIG. 6A shows a schematic side perspective cross-sectional view of packages 600 including IC chip package devices 100A-B having IC chips 108A-B mounted on chip packages 110A-B and embedded in a mold compound 120A-B, and having solder 645A-B applied to their side wall pads 160A-B of elements 150A-B.

In some cases, solder 645A-B is applied to exposed side surfaces of portions 151A-B of elements 150A-B (e.g., to side wall pads 160A-B). It can be appreciated that the solder will cover at least a portion (e.g., a third) to all of the cross sectional (e.g., in directions of length L and height H) surfaces of pads 160A-B. In some cases it covers between a third and all of the surfaces of the pads. In some cases it will cover more than the all of surfaces. In some cases it will cover at least most of the surfaces and parts of solder 170A-B and parts of traces 140A-B. In some cases it will not cover any length along L that extends sideways from one of pads 160A or 160B to a lengthwise adjacent one of pads 160A or 160B.

In some cases, solder 645A-B is a solder material applied to exposed side wall pads 160A-B as surface finish. In some cases, this applying can be done by dispensing (e.g. by jet dispensing) and subsequent reflow of the dispensed solder material. In some cases, this applying can be done by dipping sidewall 122A-B into liquid solder (which will adhere to sidewalls 160A-B because they are formed of metal, but not adhere very well to the materials of compound 120A-B or substrate 102A-B).

In some cases, solder 645A-B may be a surface finish that is not solder, such as an organic solderability preservative (OSP), metal or metal stacks deposited by electro less plating or sputtering onto sidewalls 160A-B (e.g., but not onto compound 120A-B or substrate 102A-B). In some cases it is an organic solderability preservative (OSP). In some cases it is a metal deposited by electro less plating or sputtering. In some cases it is metal stacks deposited by electro less plating or sputtering.

In some cases, solder 645A-B may be an insulating material that is not solder, deposited onto sidewalls 160A-B (e.g., but not onto compound 120A-B or substrate 102A-B). This may allow for capacitive coupling to the side wall pads (e.g., between each pair of pads 160A-B) while avoiding galvanic contact (e.g., between each pair of pads 160A-B).

FIG. 6B shows a schematic side perspective cross-sectional view of packages: (1) including multiple IC chip package devices having IC chips mounted on chip packages and embedded in a mold compound; (2) having solder applied to and attaching their opposing side wall pads to each other; and (3) mounted on a printed circuit board (PCB). FIG. 6B shows a schematic side perspective cross-sectional view of packages 600: (1) including multiple IC chip package devices 100A-B having IC chips 108A-B mounted on chip packages 110A-B and embedded in a mold compound 120A-B; (2) having solder 645 applied to and attaching their opposing side wall pads 160A-B of elements 150A-B to each other; and (3) mounted on a printed circuit board (PCB) 602.

In some cases, solder 645 directly connects (such as by physically attaching and electrically coupling) exposed side surfaces of portions 151A-B of elements 150A-B (e.g., to side wall pads 160A-B), respectively. It can be appreciated that the solder 645 may cover at least a portion to more than all of the cross sectional surfaces of pads 160A-B as described for solder 645A-B. In some cases, solder 645A-B may be described as a coating on the solder sidewall (e.g., pads 160A-B).

In some cases, the material of solder 645 is a solder alloy, some other alloy or pure metal. In some cases, the material of solder 645 is a solder formed after reflow of a solder paste, a solder flux, or a solder material as known in the art. In some cases, solder 645 may be a reflow of a solder material applied to exposed side wall pads 160A-B as a surface finish such as described for solder 645A-B. In some cases, solder 645 may be a surface finish that is not solder such as described for solder 645A-B. In some cases, solder 645 may be an insulating material that is not solder such as described for solder 645A-B.

In some cases devices 10A-B are also mounted onto horizontal surface 623 of PCB 602. FIG. 6B shows IC chip package devices 100A-B having balls 128A-B applied to and attaching (e.g., physically attaching and electrically coupling) surface contacts or traces 136A-B to their opposing surface contacts or traces 606A-B of PCB 602.

PCB 602 is shown having laminate 607; traces 606 formed over a top of laminate 607; solder stop 604 formed over a top of traces 606 and laminate 607 that is exposed or horizontally between traces 606; traces or surface contacts 636 formed over a bottom of laminate 607; solder stop 634 formed over a bottom of laminate 607 that is exposed or horizontally between contacts 636. In some cases, solder stop 634 is also formed over conductors 636 but then opened (e.g., etched) to expose the pads 636 for soldering (e.g., to have solder bumps formed onto pads 636). In some cases, solder stop 634 also extends on parts of the conductor pattern that are not pads for solder connections. It some embodiments, laminate 607 is not exposed (e.g., at surface 605) but is covered by solder stop 634.

In some cases, laminate 607 has top surface 603 having openings or recesses into which (or upon which—not shown) conductor material traces 606 are formed. Traces 606 may physically contact (e.g., touch) or be coupled to other conductor material traces, contacts, or vias within one or more layers of laminate 607, such as to be electrically connected (e.g., with less than 10 Ohms or zero electrical resistance) to traces 636. These electrical connections may be for power, ground, and/or data signal transmission.

In some cases, balls 128A-B directly connects (such as by physically attaching and electrically coupling) exposed traces 136A-B to traces 606 of PCB 602. It can be appreciated that the balls 128A-B may cover at least a portion to more than all of the top view (e.g., along width W and length L) cross sectional surfaces of traces 136A-B and 606 as described for solder 645A-B covering the side view surfaces of pads 160A-B.

In some cases, balls 128A-B may be a solder material applied to exposed traces 136A-B and traces 606 such as a surface finish as described for solder 645A-B. In some cases, the material of balls 128A-B is a solder alloy, some other alloy or pure metal. In some cases, balls 128A-B may be a surface finish that is not solder such as described for solder 645A-B. In some cases, balls 128A-B may be an insulating material that is not solder such as described for solder 645A-B. In some cases, surface contacts or traces 136A-B are directly connected by balls 128A-B to their opposing surface contacts or traces 606.

In some cases, balls 128A-B may be a joint of solder material formed by reflow soldering in the same process (e.g., same solder deposition and reflow processes) as the connections of solder 645. In some cases, balls 128A-B may be formed by separate reflow soldering process (e.g., a different solder deposition and reflow processes) as compared to the connections of solder 645.

In some cases, solder 645 may be some solder paste or flux may be added between the packages 110A-B for easier formation of the solder connection between the packages. In some cases, solder 645 may be some solder paste or flux may be added between the packages 110A-B after a first reflow process to form the PCB-mounting of balls 128A-B, while the connection 645 between the packages 110A-B is formed in a second reflow step.

According to embodiments, although FIGS. 6A-B show package devices 100A and 100B; either or both of those devices may be any package device described for devices 300A, 300B, 300C, 400 or 500. In some cases, the device on the left (shown as device 100A) may be any package device described for devices 100, 100A, 100B, 300A, 300B, 300C, 400 or 500; and the device on the right (shown as device 100B) may be a different one of any package device described for devices 100, 100A, 100B, 300A, 300B, 300C, 400 or 500.

In some cases, instead of elements 150A the device on the left (shown as device 100A) may have elements 350A, 450, or 550 such described for devices 100A, 300A, 300C, 400 or 500; and instead of elements 150B the device on the right (shown as device 100B) may have elements 350B, 450, or 550 such described for devices 100B, 300B, 300B, 400 or 500.

In some cases, FIGS. 6A-B describe attaching the sidewall pads of one package device (e.g., of devices 100, 100A, 100B, 300A, 300B, 300C, 400 or 500) having sidewall conductive elements or contact pads for side-by-side connecting one package having an IC chip to another package, to the sidewall pads of another of such package devices (e.g., of devices 100, 100A, 100B, 300A, 300B, 300C, 400 or 500); and attaching the bottom of those two package devices to the top of a PCB.

FIG. 7A shows a schematic side perspective cross-sectional view of packages including: (1) an IC chip package device having IC chip mounted on a chip package and embedded in a mold compound; (2) having solder applied to and attaching its side wall pads to opposing sidewall pads or traces of a 3-dimensional (3D) molded interconnect device (MID); and (3) mounted onto a horizontal surface of the 3D MID. FIG. 7A shows a schematic side perspective cross-sectional view of packages 700 including: (1) IC chip package device 100A having IC chip 108A mounted on a chip package 110A and embedded in a mold compound 120A; and (2) having solder 645 applied to and attaching (e.g., physically attaching and electrically coupling) its side wall pads 160A of elements 150A to opposing sidewall pads or traces 728 on sidewall 722 of a 3-dimensional (3D) molded interconnect device (MID) 710. In some cases device 100A is also mounted onto horizontal surface 723 of the 3D MID 710.

In some cases, solder 645 directly connects (such as by physically attaching and electrically coupling) exposed side surfaces of portions 151A of elements 150A (e.g., of side wall pads 160A) to opposing sidewall pads or traces 728 on sidewall 722 of 3D MID 710.

It can be appreciated that the solder 645 of FIG. 7A may cover at least a portion, to more than all of the cross sectional surfaces of pads 160A as described for solder 645A of FIGS. 6A-B. In some cases, the material of solder 645 is a solder alloy, or solder material as described for solder 645A of FIGS. 6A-B. In some cases, solder 645 may be a solder material or non-solder applied to exposed side wall pads 160A as a surface finish; or may be an insulating material, such as described for solder 645A-B of FIGS. 6A-B.

In some cases, device 100A has balls 128A applied to and attaching (e.g., physically attaching and electrically coupling) its bottom surface contacts or traces 136A to opposing top surface contacts or traces 706 formed on or in horizontal surface 723 of the 3D MID 710. It can be appreciated that the balls 128A may cover at least a portion to more than all of the top view (e.g., along width W and length L) cross sectional surfaces of traces 136A and 706 as described for solder 645A-B covering the side view surfaces of pads 160A-B.

MID 710 is shown having horizontally (or laterally) disposed (traces or) surface contacts 706 formed over a top of horizontal surface 723 (such as a surface of a dielectric, laminate or solder stop); and vertically (or height) disposed (traces or) surface contacts 728 formed over a top of vertical surface 722 (such as a surface of a dielectric, laminate or solder stop). It has height greater than H, which may be between 2×H and 3×H. It has width greater than W, which may be between 2×W and 3×W.

In some cases, MID 710 is a 3-dimensional interconnect device with at least (1) vertically disposed conductor material traces and surface contacts along (e.g., such as contacts 728) and below vertical surface 722 (e.g., extending in a path along height H and contacting other traces and contacts through horizontally extending vias or via contacts extending in a path along the direction of width W); and (2) horizontally disposed conductor material traces and surface contacts along (e.g., such as contacts 706) and below horizontal surface 723 (e.g., extending in a path along height W and contacting other traces and contacts through vertically extending vias or via contacts extending in a path along the direction of height H). In some cases, MID 710 is not considered a PCB due to having the vertically disposed surface contacts 728 formed over a top of vertical surface 722 (e.g., in addition to contacts 706 on surface 723).

In some cases, the material of balls 128A is a solder alloy, other alloy, metal, or solder material as described for solder 645A of FIGS. 6A-B. In some cases, balls 128A may be a solder material or non-solder applied as a surface finish; or may be an insulating material, such as described for solder 645A-B of FIGS. 6A-B.

In some cases, balls 128A may be a joint of solder material formed by reflow soldering in the same process (e.g., same solder deposition and reflow processes) as the connections of solder 645. In some cases, balls 128A may be formed by separate reflow soldering process (e.g., a different solder deposition and reflow processes) as compared to the connections of solder 645.

In some cases, solder 645 may be formed from some solder paste or flux added between the package 110A and MID 700 for easier formation of the solder connection between the packages. In some cases, solder 645 may be formed from some solder paste or flux may be added between the package 110A and MID 700 after a first reflow process to form the PCB-mounting of balls 128A, while the connection 645 between the package 110A and MID 700 is formed in a second reflow step.

In some cases, while a PCB (e.g., PCB 602) is a planar interconnect device there are also examples of 3-dimensional interconnect devices such as 3D MID 710. In contrast to a PCB (e.g., PCB 602), 3D MID 710 may have contact pads 728 and 706 that are not all in the same plane (e.g., that are on vertical sidewall 722 and on horizontal surface 723, respectively) and that may also have different orientations (e.g., contact pads 728 and 706 are oriented vertically and horizontally, respectively). In some cases, FIG. 7A shows a second level interconnect from package 110A to third interconnect device 710.

Although FIG. 7A shows contact pads 160A and 128A connected (e.g., physically attached and electrically coupled) to the same device (e.g., to contact pads 728 and 706 of 3D MID 710), embodiments are considered where contact pads 160A are connected to one device (e.g., to contact pads 728 of a 3D MID 710, or vertical contact pads of a PCB), but contact pads 128A are connected to a different device (e.g., to horizontal contact pads of a separate PCB or another MID; either one is not part of the device pads 128A are connected to).

In some cases, FIG. 7A shows how side wall pads 160A can be used to make contact to such pads 728 of 3D interconnect device, for example to molded interconnect device (MID) 710.

FIG. 7B shows a schematic side perspective cross-sectional view of packages including: (1) multiple IC chip package devices, each having an IC chip mounted on a chip package and embedded in a mold compound; (2) each having solder applied to and attaching its side wall pads to opposing sidewall pads or traces of a 3-dimensional (3D) molded interconnect device (MID); and (3) each mounted onto another IC chip package device or onto a horizontal surface of the 3D MID.

FIG. 7B shows a schematic side perspective cross-sectional view of packages 701 including: (1) IC chip package device 100A having IC chip 108A mounted on a chip package 110A and embedded in a mold compound 120A; and (2) having solder 645 applied to and attaching (e.g., physically attaching and electrically coupling) its side wall pads 160A of elements 150A to opposing sidewall pads or traces 728A in a first array pattern at a first vertical level on sidewall 722 of a 3-dimensional (3D) molded interconnect device (MID) 711. In some cases device 100A is also mounted by an adhesive layer 736A onto horizontal top surface 124′ of device 100A′.

FIG. 7B also shows packages 701 including: (1) IC chip package device 100A′ having IC chip 108A′ mounted on a chip package 110A′ and embedded in a mold compound 120A′; and (2) having solder 645′ applied to and attaching (e.g., physically attaching and electrically coupling) its side wall pads 160A′ of elements 150A′ to opposing sidewall pads or traces 728B in a second array pattern at a different second vertical level (e.g., below the first level) on sidewall 722 of 3D MID 711. In some cases device 100A′ is also mounted by an adhesive layer 736A′ onto horizontal top surface 124″ of device 100A″.

FIG. 7B also shows packages 701 including: (1) IC chip package device 100A″ having IC chip 108A″ mounted on a chip package 110A″ and embedded in a mold compound 120A″; and (2) having solder 645″ applied to and attaching (e.g., physically attaching and electrically coupling) its side wall pads 160A″ of elements 150A″ to opposing sidewall pads or traces 728C in a third array pattern at a different third vertical level (e.g., below the second level) on sidewall 722 of 3D MID 711. In some cases device 100A″ is also mounted onto horizontal surface 723 of the 3D MID 710.

In some cases, solder 645, 645′ and 645″ directly connect (such as by physically attaching and electrically coupling) exposed side surfaces of portions 151A, 151A′, and 151A″ (e.g., of side wall pads 160A, 160A′, and 160A″) to opposing sidewall pads or traces 728A, 728B and 728C, respectively on sidewall 722 of 3D MID 711.

MID 711 is shown having horizontally (or laterally) disposed (traces or) surface contacts 707 formed over a top of horizontal surface 723 (such as a surface of a dielectric, laminate or solder stop); and vertically (or height) disposed (traces or) surface contacts 728A-C formed over a top of vertical surface 722 (such as a surface of a dielectric, laminate or solder stop). It has height greater than 3×H, which may be between 4×H and 6×H. It has width greater than W, which may be between 2×W and 3×W.

In some cases, MID 711 is a 3-dimensional interconnect device with at least (1) 3 sets or arrays of vertically disposed conductor material traces and surface contacts along (e.g., such as contacts 728A-C) and below vertical surface 722 (e.g., extending in a path along height H and contacting other traces and contacts through horizontally extending vias or via contacts extending in a path along the direction of width W); and (2) horizontally disposed conductor material traces and surface contacts along (e.g., such as contacts 707) and below horizontal surface 723 (e.g., extending in a path along height W and contacting other traces and contacts through vertically extending vias or via contacts extending in a path along the direction of height H). In some cases, MID 711 is not considered a PCB due to having the vertically disposed surface contacts 728A-C formed over a top of vertical surface 722 (e.g., in addition to contacts 707 on surface 723).

It can be appreciated that the solder 645, 645′ and 645″ of FIG. 7B may cover at least a portion, to more than all of the cross sectional surfaces of pads 160A, 160A′, and 160A″ as described for solder 645A of FIGS. 6A-B. In some cases, the material of solder 645, 645′ and 645″ is a solder alloy, other alloy, metal, or solder material as described for solder 645A of FIGS. 6A-B. In some cases, solder 645, 645′ and 645″ may be a solder material or non-solder applied to exposed side wall pads 160A, 160A′, and 160A″ as a surface finish; or may be an insulating material, such as described for solder 645A-B of FIGS. 6A-B.

In some cases, device 100A″ has balls 128A″ applied to and attaching (e.g., physically attaching and electrically coupling) its bottom surface contacts or traces 136A to opposing top surface contacts or traces 707 formed on or in horizontal surface 723 of the 3D MID 710. It can be appreciated that the balls 128A″ may cover at least a portion to more than all of the top view (e.g., along width W and length L) cross sectional surfaces of traces 136A″ and 707 as described for solder 645A-B covering the side view surfaces of pads 160A-B.

In some cases, the material of balls 128A″ is a solder alloy, other alloy, metal, or solder material as described for solder 645A of FIGS. 6A-B. In some cases, balls 128A″ may be a solder material or non-solder applied as a surface finish; or may be an insulating material, such as described for solder 645A-B of FIGS. 6A-B. In some cases, balls 128A″ may be a joint of solder material formed by reflow soldering in the same process (e.g., same solder deposition and reflow processes) as the connections of solder 645, 645′ and 645″. In some cases, balls 128A″ may be formed by separate reflow soldering process (e.g., a different solder deposition and reflow processes) as compared to the connections of solder 645, 645′ and 645″.

In some cases, solder 645, 645′ and 645″ may be formed from some solder paste or flux added between the packages 110A, 110A′ and 110A″ and MID 701 for easier formation of the solder connection between the packages. In some cases, solder 645, 645′ and 645″ may be formed from some solder paste or flux be added between the packages 110A, 110A′ and 110A″ and MID 701 after a first reflow process to form the PCB-mounting of balls 128A″, while the connection 645, 645′ and 645″ between the packages 110A, 110A′ and 110A″ and MID 700 is formed in a second reflow step.

In some cases, while a PCB (e.g., PCB 602) is a planar interconnect device there are also examples of 3-dimensional interconnect devices such as 3D MID 711. In contrast to a PCB (e.g., PCB 602), 3D MID 711 may have contact pads 728A-C and 707 that are not all in the same plane (e.g., that are on vertical sidewall 722 and on horizontal surface 723, respectively) and that may also have different orientations (e.g., contact pads 728A-C and 707 are oriented vertically and horizontally, respectively). In some cases, FIG. 7B shows a second level interconnect from packages 110A, 110A′ and 110A″ to third interconnect device 711. In some cases, FIG. 7B shows how side wall pads 160A, 160A′, and 160A″ can be used to make contact to such pads 728A-C of 3D interconnect device, for example to molded interconnect device (MID) 711.

Although FIG. 7B shows a package stack of 3 package devices 100A, 100A′ and 100A″ with the vertical connections realized by side wall pads 160A, 160A′, and 160A″ soldered (e.g., with solder 645, 645′ and 645″) to vertical lines of MID 711, embodiments are considered where there are fewer (e.g., only 2) or more (e.g., 4, 5 or up to 10) package devices similar to device 100A in the stack. For example, in one case there may only be devices 100A′ and 100A″ in the stack. In another example, there may be devices 100A, 100A′ and 100A″; as well as another 2 devices similar to device 100A mounted on top of device 100A (e.g., using adhesive 136A). In each of these cases, the devices 100A′ and 100A″ (and optionally a number of devices 100A) would have vertical connections realized by side wall pads (e.g., 160A′, and 160A″; and optionally a number of pads 160A) soldered (e.g., with solder 645′ and 645″; and optionally a number of solder 645) to vertical lines of MID 711.

In some cases, although FIG. 7B shows contact pads 128A, 160A, 160A′, and 160A″ connected (e.g., physically attached and electrically coupled) to the same device (e.g., to contact pads 728A-C and 706 of 3D MID 711), embodiments are considered where contact pads 160A, 160A′, and 160A″ are connected to one device (e.g., to contact pads 728A-C of a 3D MID 711, or vertical contact pads of a PCB), but contact pads 128A are connected to a different device (e.g., to horizontal contact pads of a separate PCB or another MID; either one is not part of the device pads 128A are connected to).

In addition, although FIG. 7B shows a contact pads 160A, 160A′, and 160A″ connected (e.g., physically attached and electrically coupled) to the same device (e.g., to contact pads 728A-C of 3D MID 711), embodiments are considered where contact pads 160A, 160A′, and 160A″ are connected to two or three different devices (e.g., to contact pads 728A-C of two or more of a combination of 3D MID devices and/or PCBs).

In some cases, devices 701 include a package stack of devices 100A, 100A′ and 100A″ with the vertical connections realized by side wall pads 160A, 160A′, and 160A″ soldered (e.g., with solder 645, 645′ and 645″) to vertical lines of MID 711, such as signal traces extending from contacts 728A-C and running on the surface 722 of MID 711. In some cases, a mechanical connection 736A between the packages 110A-110A′, and 736B between the packages 110A′-110A″ in the stack is by means of an adhesive layer as known in the art for performing such adhesion between packages (e.g., layers 736A-B). In some cases, the stacking of devices 100A, 100A′ and 100A″ (e.g., as shown for devices 701) reduces or avoids the need for or use of expensive Through Silicon Vias (TSVs) or Through Mold Vias (TMVs) otherwise used for Package on Package (PoP) stacking. In some cases, devices 701 provides the benefit of providing large contact surfaces (e.g., vertical cross-sectional area along H and L) between pads 160A, 160A′, and 160A″ and contacts 728A-C without TSVs or TMVs.

According to embodiments, although FIGS. 7A-B show package devices 100A, 100A′ and 100A″; any of those devices may be any package device described for devices 300A, 300B, 300C, 400 or 500. In some cases, device 100A may be any package device described for devices 100, 100A, 100B, 300A, 300B, 300C, 400 or 500; and device 100A′ may be a different one of any package device described for devices 100, 100A, 100B, 300A, 300B, 300C, 400 or 500 than device 100A; and device 100A″ may be a different one of any package device described for devices 100, 100A, 100B, 300A, 300B, 300C, 400 or 500 than device 100A or 100A′.

In some cases, FIG. 7A describes attaching the sidewall pads of one package device (e.g., of devices 100, 100A, 100B, 300A, 300B, 300C, 400 or 500) having sidewall conductive elements or contact pads for side-by-side connecting one package having an IC chip to another package; to a 3D molded interconnect device also having sidewall/vertical contacts (e.g., an array of conductive elements).

In some cases, FIG. 7B describes attaching the sidewall pads of multiple stacked ones of package devices (e.g., of devices 100, 100A, 100B, 300A, 300B, 300C, 400 and/or 500) having sidewall conductive elements or contact pads for side-by-side connecting one package having an IC chip to another package; to a 3D molded interconnect device having multiple sets or arrays of sidewall/vertical contacts or conductive elements.

FIG. 8 shows a schematic side perspective cross-sectional view of packages including: (1) an IC chip package device having IC chip mounted on a chip package and embedded in a mold compound; (2) side wall pads with opposing spring loaded contact pins of a connector pressed against them; and (3) mounted onto a horizontal surface of a PCB. FIG. 8 shows a schematic side perspective cross-sectional view of packages 800′ including: (1) IC chip package device 800 having IC chip 108 mounted on a chip package 810 and embedded in a mold compound 120; (2) side wall pads 160 with opposing spring loaded contact pins 856 of a connector 850 pressed against them; and (3) mounted onto a horizontal surface of a PCB 602.

Device 800 and package 810 may be similar to device 100 and package 110, except that surface 124 of device 800 includes notch 824.

FIG. 8 shows a schematic side perspective cross-sectional view of packages 800′ including: (1) IC chip package device 800 having IC chip 108 mounted on a chip package 110 and embedded in a mold compound 120; and (2) side wall pads 160 with opposing spring loaded contact pins 856 of a connector 850 pressed against (e.g., physically attaching and electrically coupling) its side wall pads 160 of elements 150. In some cases device 800 is also mounted onto horizontal surface 623 of PCB 602.

Connector 850 includes spring loaded contact pins 856, each slidably mounted on one end shafts 854 which have a second end mounted to central portion 850C of connector 850. Connector 850 includes springs 852 for biasing contact pins 856 away from central portion 850C and towards pads 160 with enough spring force to cause pins 856 to contact pads 160 continuously with enough cross sectional area that signals can be transmitted between the pins and pads (e.g., with enough force to maintain an electrical coupling between the pins and pads).

Connector 850 also includes top section 850A having locking hook 858 for engaging notch 824 of package device 800 with enough horizontal friction or force to hold connector 850 in horizontally fixed position with respect to device 800. In some cases, locking hook 858 engages notch 824 with sufficient horizontal force to counter the horizontal force of springs 852 that biases contact pins 856 away from central portion 850C and towards pads 160 with enough spring force to cause pins 856 to contact pads 160 as noted herein. Connector 850 also includes bottom section 850B having tab 860 for engaging the bottom surface of substrate 102 with enough vertical force to locking hook 858 vertically into notch 824 so that connector 850 is in horizontally fixed position with respect to device 800 as noted herein.

In some cases connector 850 has height greater than H, which may be between 1.2×H and 1.5×H. It has width less than W, which may be between 0.2×W and 0.8×W.

In some cases, device 800 has balls 128 applied to and attaching (e.g., physically attaching and electrically coupling) its bottom surface contacts or traces 136 to opposing top surface contacts or traces 606 formed on or in horizontal surface 623 of PCB 602.

It can be appreciated that the balls 128 may cover at least a portion to more than all of the top view (e.g., along width W and length L) cross sectional surfaces of traces 136 and 606 as described for solder 645A-B covering the side view surfaces of pads 160A-B of FIGS. 6A-B. In some cases, the material of balls 128 is a solder alloy, other alloy, metal, or solder material as described for solder 645A of FIGS. 6A-B. In some cases, balls 128 may be a solder material or non-solder applied as a surface finish; or may be an insulating material, such as described for solder 645A-B of FIGS. 6A-B.

In some cases, balls 128 may be a joint of solder material formed by reflow soldering in the same process (e.g., same solder deposition and reflow processes) as the connections of solder 645. In some cases, balls 128 may be formed by separate reflow soldering process (e.g., a different solder deposition and reflow processes) as compared to the connections of solder 645.

In some cases, devices 800′ show how the side wall pads 160 can be used with connector 850 which includes spring loaded contact pins 856 which are pressed against the side wall pads 160 for electrical contact. In some cases, connector 850 is designed to mechanically attach to package 810 by locking hook 858 into notch 824 of the package. In some embodiments, connector 850 could also be designed to mechanically attach to PCB 602; while package 810 is locked to the PCB and to connector 850.

In some cases, devices 800′ show how connector 850 includes springs 852 with contact pins 856 for physically contacting and electrically coupling to pads 160 of elements 150 such as to transmit signals (e.g., data signals) from traces 140 to traces within PCB 602. In some cases, connections from pads 160 to PCB 602 are easier established via solder balls between (e.g., bottom) surface contacts or traces of connector 850 and opposing (e.g., top) surface contacts or traces of PCB 602. In some cases, connections can be made from pads 160 to make contact to a contact of another electronic device (e.g., other than PCB 602) not located on device 800. In some cases, connections from pads 160 to another device are not permanent as a soldered connection, but may be a removable connection (e.g., without damaging connector 850 or the device to which connector 850 is connected). In some cases, connections from pads 160 to another device may use connection parts that may be changed or connections that may need to be reopened (e.g., removable). Examples could be connections to from connector 850 to displays, sensors, keyboard or direct connections to components in other PCBs. In some cases, connections can be made from pads 160 to traces within PCB 602. In some cases, connections from pads 160 to PCB 602 are easier established via solder balls between (e.g., bottom) surface contacts or traces of connector 850 and opposing (e.g., top) surface contacts or traces of PCB 602.

In some cases, connections can be made from pads 160 to make contact to a contact of another electronic device may be or include sending a signal through wires or other structure attached to the contact pins 856/854, and extending horizontally (sideways) away from connector 850, to a horizontally parallel package mounted (e.g., on PCB 602) beside the connector/package (e.g., to a side by side mounted other package).

In some cases, connections can be made from pads 160 to make contact to a contact of another electronic device may be or include sending a signal from pads 160 to connector 850; from connector 850 to a cable or wire (considered part of or not part of but attached to connector 850) used for transmitting the signals to display, sensor, or keyboard (that is not mounted on PCB 602). The cable or wire may have signal wires or paths attached to the contact pins 856/854, and extending horizontally (sideways) away from connector 850, to the display, sensor, or keyboard (which may be a different device or part of a different device than the one including device 800.

According to embodiments, although FIG. 8 show packages device 800, that device may be any package device described for devices 100, 100A, 100B, 300A, 300B, 300C, 400 or 500, with the exception of having notch 824.

In some cases, FIG. 8 describes attaching the sidewall pads of one package device (e.g., of devices 100, 100A, 100B, 300A, 300B, 300C, 400 or 500) having sidewall conductive elements or contact pads for side-by-side connecting one package having an IC chip to another package; to a connector having horizontally oriented spring loaded contact pins.

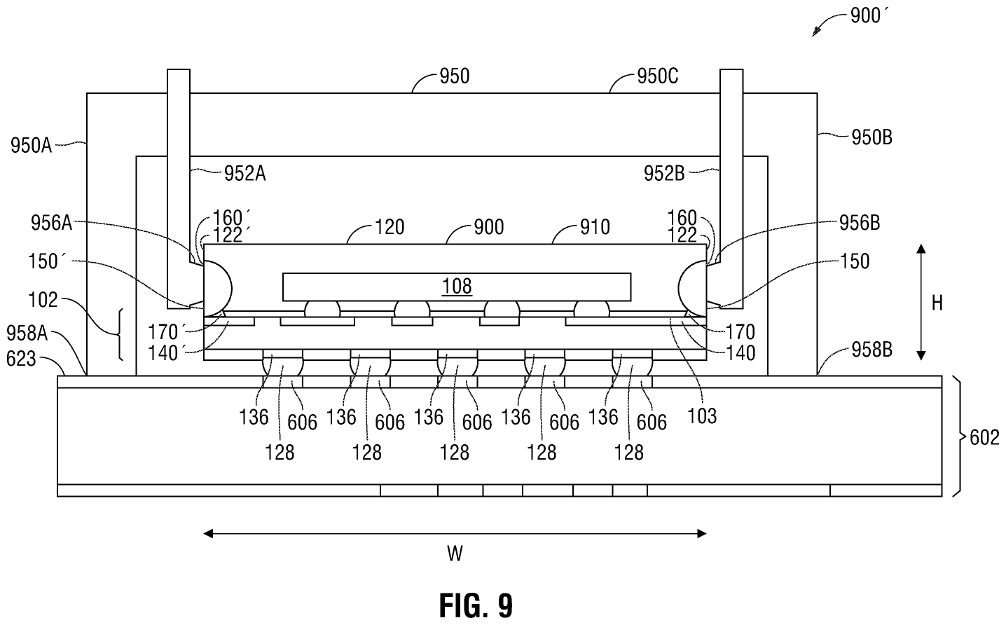

FIG. 9 shows a schematic side perspective cross-sectional view of packages including: (1) an IC chip package device having IC chip mounted on a chip package and embedded in a mold compound; (2) horizontally opposing sets of side wall pads with opposing contact tips of flat springs of a connector pressed against them; and (3) mounted onto a horizontal surface of a PCB (and the connector may be mounted onto the PCB as well). FIG. 9 shows a schematic side perspective cross-sectional view of packages 900′ including: (1) an IC chip package device 900 having IC chip mounted 108 on a chip package 910 and embedded in a mold compound 120; (2) horizontally opposing sets of side wall pads 160 and 160′ with opposing contact tips 956A-B of flat springs 952A-B of a connector 950 pressed against them; and (3) mounted onto a horizontal surface 623 of a PCB 602.

Device 900 and package 910 may be similar to device 100 and package 110, except that it also includes traces 140′ that may extend horizontally along or under surface 103 to contact conductor material solder 170′ and/or conductive elements 150′ having sidewall pads 160′ on surface 122′ which is horizontally opposite to (e.g., on horizontally opposing exposed sidewall ends of device 900 or package 910 along direction of width W). In some cases, traces 140′ may physically contact or be coupled to other conductor material traces, contacts, or vias within one or more layers of laminate 107 (e.g., of substrate 102) to contact conductor material solder 170′ and/or conductive elements 150′. These electrical connections may be for power, ground, and/or data signal transmission.

FIG. 9 shows a schematic side perspective cross-sectional view of packages 900′ including: (1) IC chip package device 900 having IC chip 108 mounted on a chip package 110 and embedded in a mold compound 120; and (2) opposing side wall pads 160 and 160′ with opposing flat springs 952A-B biased (e.g., loaded) opposing contact tips 956A-B of connector 950 pressed against (e.g., physically attaching and electrically coupling) its opposing side wall pads 160 and 160′ of elements 150 and 150′, respectively. In some cases device 900 is also mounted onto horizontal surface 623 of PCB 602. In some cases connector 950 is mounted onto surface 623 of PCB by mounts 958A-B. In some cases it is not.

Connector 950 includes opposing contact tips 956A-B, each biased (e.g., loaded) inwards towards pads 160 and 160′, by one end of opposing flat springs 952A-B, respectively which have a second end mounted to central portion 950C of connector 950. Connector 950 includes springs 952A-B for biasing contact pins 956A-B horizontally (e.g., along direction of width W) inwards towards pads 160 and 160′; and away from end sections 950A and 950B, respectively, with enough spring force to cause pins 956A-B to contact pads 160 and 160′ continuously with enough cross sectional area that signals can be transmitted between the pins and pads (e.g., with enough force to maintain an electrical coupling between the pins and pads).

Connector 950 includes opposing end sections 950A and 950B attached or forming opposing vertical extensions of central portion 950C as shown. In some cases connector 950 is mounted onto surface 623 of PCB by mounts 958A-B as known in the art (e.g., by adhesive or a metal to metal attachment). In some cases, mounts 958A-B engage surface 623 with enough vertical and horizontal friction or force to hold connector 950 in horizontally and vertically in a fixed position with respect to PCB 602.

In some cases connector 950 has height greater than H, which may be between 1.5×H and 3×H. It has width greater than W, which may be between 1.2×W and 1.8×W.

In some cases, device 900 has balls 128 applied to and attaching (e.g., physically attaching and electrically coupling) its bottom surface contacts or traces 136 to opposing top surface contacts or traces 606 formed on or in horizontal surface 623 of PCB 602.

It can be appreciated that the balls 128 may cover at least a portion to more than all of the top view (e.g., along width W and length L) cross sectional surfaces of traces 136 and 606 as described for solder 645A-B covering the side view surfaces of pads 160A-B of FIGS. 6A-B. In some cases, the material of balls 128 is a solder alloy, other alloy, metal, or solder material as described for solder 645A of FIGS. 6A-B. In some cases, balls 128 may be a solder material or non-solder applied as a surface finish; or may be an insulating material, such as described for solder 645A-B of FIGS. 6A-B.

In some cases, balls 128 may be a joint of solder material formed by reflow soldering in the same process (e.g., same solder deposition and reflow processes) as the connections of solder 645. In some cases, balls 128 may be formed by separate reflow soldering process (e.g., a different solder deposition and reflow processes) as compared to the connections of solder 645.

In some cases, devices 900′ show how connector 950 includes flat springs 952A-B with contact tips 956A-B for physically contacting and electrically coupling to pads 160 and 160′ of elements 150 and 150′ such as to transmit signals (e.g., data signals) from traces 140 and 140′ to traces within PCB 602. In some cases, devices 900′ show how connector 950 includes flat springs 952A-B with contact tips 956A-B for physically contacting and electrically coupling to pads 160 of elements 150 such as to transmit signals (e.g., data signals) from traces 140 to traces within PCB 602. In some cases, connections from pads 160 to PCB 602 or another electronic device can be made as described above for connections from pads 160 to another device through connector 850.

According to embodiments, although FIG. 9 show packages device 900, that device may be any package device described for devices 100, 100A, 100B, 300A, 300B, 300C, 400 or 500, with the exception of having traces 140′ that may extend horizontally along or under surface 103 to contact conductor material solder 170′ and/or conductive elements 150′ having sidewall pads 160′ on surface 122′ which is horizontally opposite to (e.g., on horizontally opposing exposed sidewall ends of device 900 or package 910 along direction of width W).

In some cases, FIG. 9 describes attaching the sidewall pads of one package device (e.g., of devices 100, 100A, 100B, 300A, 300B, 300C, 400 or 500) having sidewall conductive elements or contact pads for side-by-side connecting one package having an IC chip to another package; to a connector having horizontally oriented flat spring with contact tips.

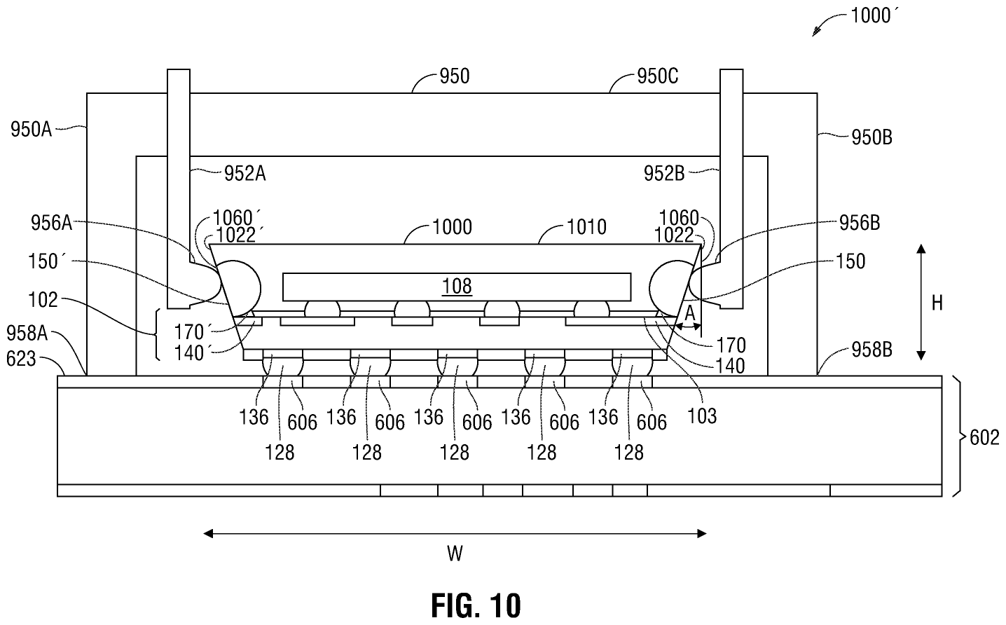

FIG. 10 shows a schematic side perspective cross-sectional view of packages including: (1) an IC chip package device having IC chip mounted on a chip package and embedded in a mold compound and having two opposing beveled sidewalls; (2) horizontally opposing sets of beveled side wall pads with opposing contact tips of flat springs of a connector pressed against them; and (3) mounted onto a horizontal surface of a PCB (and the connector may be mounted onto the PCB as well). FIG. 10 shows a schematic side perspective cross-sectional view of packages 1000′ including: (1) an IC chip package device 1000 having IC chip mounted 108 on a chip package 1010 and embedded in a mold compound 120 and having two opposing beveled sidewalls 1022 and 1022′; (2) horizontally opposing sets of beveled side wall pads 1060 and 1060′ with opposing contact tips 956A-B of flat springs 952A-B of a connector 950 pressed against them; and (3) mounted onto a horizontal surface 623 of a PCB 602.

Device 1000 and package 1010 may be similar to device 900 and package 910, except that it also includes two opposing beveled sidewalls 1022 and 1022′ instead of vertical sidewalls 122 and 122′; beveled side wall contact pads 1060 and 1060′ instead of vertical contact pads 160 and 160′. In some cases, “beveled” describes sidewalls 1022 and 1022′ being tilted inwards (e.g., along direction of width W) towards chip 108 by angle A beyond vertical (e.g., beyond tangential to or beyond 90 degrees with respect to surface 103). In some cases, angle A is between 5 and 35 degrees. In some cases it is between 15 and 25 degrees.

In some cases, beveled sidewalls 1022 and 1022′ (or beveled side wall contact pads 1060 and 1060′) provide increased friction or force between contact tips 956A-B and contact pads 1060 and 1060′. This may increase the electrical coupling (and decrease electrical resistance) between the tips and pads. In cases the increased friction or force includes an upwards (e.g., along direction of height H away from surface 623) force on beveled sidewalls 1022 and 1022′ (or beveled side wall contact pads 1060 and 1060′. The additional vertical component of the force may help to prevent lifting off the connector from the PCB

In some cases, beveled sidewalls 1022 and 1022′ may be formed during singulation of device 1000 or package 1010. This singulation may be as described for singulating devices 100A-B or 300A-B from devices 201 and 301, respectively.

FIG. 10 shows a schematic side perspective cross-sectional view of packages 1000′ including opposing beveled side wall pads 1060 and 1060′ with opposing flat springs 952A-B biased (e.g., loaded) opposing contact tips 956A-B of connector 950 pressed against (e.g., physically attaching and electrically coupling) its opposing beveled side wall pads 1060 and 1060′ of elements 150 and 150′, respectively. In some cases device 1000 is also mounted onto horizontal surface 623 of PCB 602. In some cases connector 950 is mounted onto surface 623 of PCB by mounts 958A-B. In some cases it is not.

Connector 950 may be the same as in FIG. 9 except that springs 952A-B bias contact pins 956A-B horizontally inwards towards beveled pads 1060 and 1060′ similar to towards pads 160 and 160′ as in FIG. 9.

In some cases, device 1000 has balls 128 applied to and attaching (e.g., physically attaching and electrically coupling) its bottom surface contacts or traces 136 to opposing top surface contacts or traces 606 formed on or in horizontal surface 623 of PCB 602 as described for device 900 and PCB 602 in FIG. 9.

Although FIGS. 9-10 shows contact pads 160/160′ and 1060/1060′ on opposing sidewalls 122/122′ and 1022/1022′, embodiments are considered where one sidewall of contact pads (e.g., 160 or 160′; and 1060 or 1060′) exist on either sidewall 122 or 122′; and 1022 or 1022′. In some of these cases, connector 900′ or 1000′ then only has one of springs 952A or 952B; and bias contact pins 956A or 956B, respectively. In other of these cases, connector 900′ or 1000′ then has both of springs 952A-B; but only one of bias contact pins 956A or 956B, respectively. Here, the spring without the contact pin can contact the opposing sidewall (e.g., opposite the side of the connector with contact pins) to provide some support or counterforce for the spring on the first side.

In some cases, devices 1000′ show how connector 950 includes flat springs 952A-B with contact tips 956A-B for physically contacting and electrically coupling to beveled pads 1060 and 1060′ of elements 150 and 150′ such as to transmit signals (e.g., data signals) from traces 140 and 140′ to traces within PCB 602. In some cases, devices 1000′ show how connector 950 includes flat springs 952A-B with contact tips 956A-B for physically contacting and electrically coupling to beveled pads 1060 and 1060′ of elements 150 and 150′ such as to transmit signals (e.g., data signals) from traces 140 and 140′ to traces within PCB 602. In some cases, connections from beveled pads 1060 and 1060′ to PCB 602 or another electronic device can be made as described above for connections from pads 160 to another device through connector 850.

According to embodiments, although FIG. 10 show packages device 1000, that device may be any package device described for devices 100, 100A, 100B, 300A, 300B, 300C, 400 or 500, with the exception of having traces 140′ that may extend horizontally along or under surface 103 to contact conductor material solder 170′ and/or conductive elements 150′ having sidewall pads 160′ on surface 122′ which is horizontally opposite to (e.g., on horizontally opposing exposed sidewall ends of device 900 or package 910 along direction of width W); and has beveled sidewalls 1022 and 1022′ (and beveled side wall contact pads 1060 and 1060′).

In some cases, FIG. 10 describes attaching the sidewall pads on opposing sides of one package device (e.g., of devices 100, 100A, 100B, 300A, 300B, 300C, 400 or 500) having sidewall conductive elements or contact pads for side-by-side connecting one package having an IC chip to another package; to a connector having horizontally oriented flat spring with contact tips, but where the package has beveled sidewalls (apparently formed during singulation) to allow for better fixation to the connector having flat springs with contact tips.

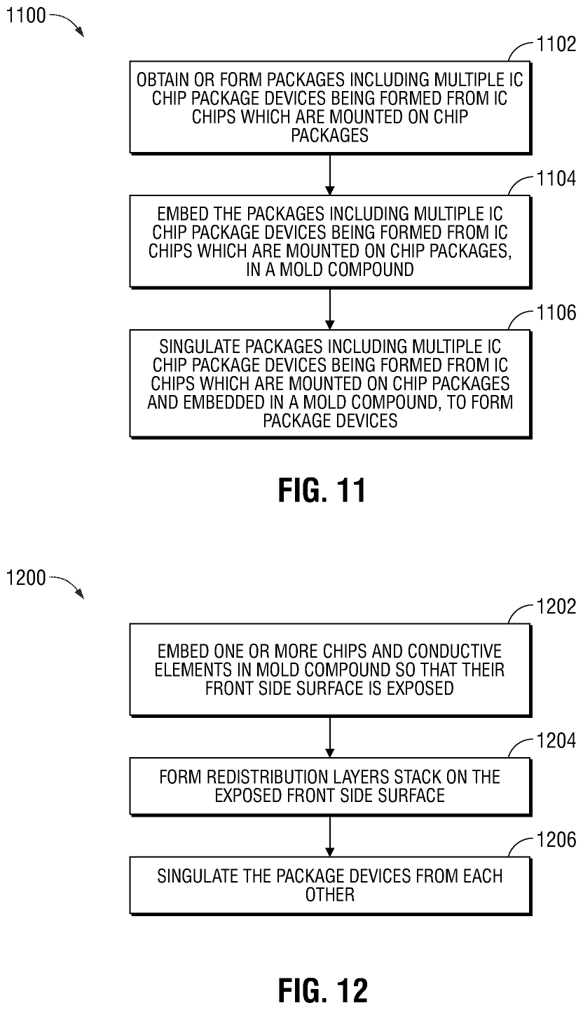

FIG. 11 shows example embodiments of processes to form multiple integrated circuit (IC) chip package devices that each include an IC chip mounted on an IC package, where each package device has an array or row of sidewall contact pads for connecting to another package device. In some cases, FIG. 11 shows embodiments of processes 1100 for producing any of package devices 100, 100A, 100B, 300A, 300B, 300C, 400, 800, 900 or 1000.

In some cases, FIG. 11 shows embodiments of processes for producing flip chip that are produced on strip level, such as using laminate 207 or substrate 202 as the “strip” upon which multiple packages 110, 110A, 110B, 310A, 310B, 310C, 410, 510, 810, 910 or 1010; some or all of which are formed at the same time (e.g., such as forming the same layer of all of the devices at the same time). There may be between 2 and 1000 devices on such a strip or substrate. In some cases there are between 20 and 200. In some cases, such a strip is a piece of substrate material (e.g., substrate 202) including all the substrates of the individual packages to be produced.

Processes 1100 may begin with block 1102 where packages (e.g., see packages 200 and 300) including multiple IC chip packages being formed of or from IC chips which are mounted on chip packages (and are to be embedded in a mold compound) are obtained or formed.

In some cases, block 1102 includes forming or obtaining packages (e.g., packages 200, 300 or the like for forming package devices 100, 100A, 100B, 300A, 300B, 300C, 400, 800, 900 or 1000) including multiple integrated circuit (IC) chip packages (e.g., 110, 110A, 110B, 310A, 310B, 310C, 410, 510, 810, 910 or 1010) each having an IC chip (e.g., chip 108, 108A or 108B) and conductive elements (e.g., elements 250, 350; or combined portions of elements 350A, 450, or 550) mounted on top surface 103 of each chip package.

In some cases such forming may include creating (e.g., manufacturing or processing to form) the chips at the same location; or processing progression or steps that will include forming the packages (e.g., see packages 200 and 300) including multiple IC chip package devices, infusing with mold compound (and optionally dicing). This may not include transporting the chips in a box or other container. It may include a handler moving the chips from one processing tool or device to a packaging tool or a solder reflow tool.

In some cases such forming may include creating (e.g., manufacturing or processing to form) the chips at a different location, another building or another processing “room” or location where the packages are manufactured than that of forming the packages (e.g., see packages 200 and 300) including multiple IC chip package devices, infusing with mold compound and dicing. This may include transporting the packages in a box or other container that does not include padding or protection for the chips. It may include a handler moving the chips from one container to a packaging tool or a solder reflow tool.

In some cases such forming may include creating (e.g., manufacturing or processing to form) the chips at an outside vendor, another facility, another building or another location than that of forming the packages (e.g., see packages 200 and 300) including multiple IC chip package devices, infusing with mold compound and dicing. This may include transporting the packages in a box or other container that includes padding or protection for the chips. It may include a handler moving the chips from one protected container to a packaging tool or a solder reflow tool.

In some cases, block 1102 includes descriptions for forming packages 200 or 300 of FIG. 2A or 3A, respectively. In some cases, block 1102 includes descriptions for forming a strip such as laminate 207 or substrate 202 having multiple package devices 200 or 300 without mold compound 220 (e.g., prior to compound 220), and prior to singulation (e.g., of the package devices 100A-B or 300A-B).

After block 1102 processes 1100 continues to block 1104 where packages (e.g., see packages 201 and 301) including multiple IC chip package devices being formed from IC chips which are mounted on chip packages, are embedded in a mold compound.

In some cases, block 1104 includes embedding the IC chips and conductive elements of block 1102 in a mold compound, the mold compound formed on the top surface 103 of the packages (e.g., packages 200, 300 or the like for forming package devices 100, 100A, 100B, 300A, 300B, 300C, 400, 800, 900 or 1000).

In some cases, block 1104 includes descriptions for forming packages 201 or 301 of FIG. 2B or 3B, respectively. In some cases, block 1104 includes descriptions for forming a strip such as laminate 207 or substrate 202 having multiple package devices 201 or 301 with mold compound 220 (e.g., after infusion of compound 220), and prior to singulation (e.g., of the package devices 100A-B or 300A-B). In some cases, block 1104 includes compound 120 being molded onto and over all of the surfaces of the chips and onto the conductive elements by mold pressing using a mold press tool.

After block 1104 processes 1100 continues to block 1106 where packages (e.g., see packages 201 and 301) including multiple IC chip package devices being formed from IC chips which are mounted on chip packages and embedded in a mold compound, are singulated to form package devices (e.g., package devices 100A-B or 300A-B).

In some cases, block 1106 includes singulating the packages through the conductive elements (e.g., elements 250, 350; or combined portions of elements 350A, 450, or 550) to form package devices (e.g., package devices 100, 100A, 100B, 300A, 300B, 300C, 400, 800, 900 or 1000) each having an integrated circuit (IC) chip package (e.g., 110, 110A, 110B, 310A, 310B, 310C, 410, 510, 810, 910 or 1010), an IC chip (e.g., chip 108, 108A or 108B), and portions of conductive elements (e.g., elements 150, 350, 450, and/or 550 such as mounted on top surface 103 of each chip package) with exposed vertical contact pads (e.g., 160, and the like) at a vertical sidewall 122 where the package was singulated.

In some cases, block 1106 includes descriptions for singulating packages 201 or 301 of FIG. 2B or 3B, respectively to form package devices 100A-B or 300A-B. In some cases, block 1106 includes descriptions singulating a strip such as laminate 207 or substrate 202 having multiple package devices 201 or 301 with mold compound 220 (e.g., after infusion of compound 220).

In some cases, after over molding (e.g., with compound 220 to form devices 201 or 301 of FIG. 2B or 3B) the packages of devices 201 or 301 are singulated to form devices 100A-B or 300A-B of FIG. 2C or 3C by cutting between the dies (e.g., chips 108A-B) and through the metal balls (e.g., elements 250 or 350) along pattern 255. In some cases, cutting can be by mechanical dicing or laser. In some cases, as a result of singulating, a part of each of elements 250 or 350 becomes part of the left package 110A or 310A, and another part becomes part of the right package 110B or 310B. In some cases, the cut surface of elements 250 or 350 along pattern 255 forms trenches 256, and forms the side wall pads 160A-B or 360A-B.

FIG. 12 shows example embodiments of processes to form multiple integrated circuit (IC) chip package devices that each include an IC chip mounted on an IC package, where each package device has an array or row of sidewall contact pads for connecting to another package device, and where the package device is an embedded wafer level ball grid array (eWLB) package. In some cases, FIG. 12 shows embodiments of processes 1100 for producing many of package devices 500.

Processes 1200 may begin with block 1202 where chip 108 (e.g., the “die”) and conductive elements 550 are embedded in mold compound 120 so that their front side (e.g., surface 525) is exposed (e.g., before forming stack 502). In some cases such forming may include creating (e.g., manufacturing or processing to form) the chips 108 at the same location, another location, a vendor, etc. as described for block 1102.

In some cases, block 1202 includes embedding IC chips (e.g., chips 108) and conductive elements (e.g., elements 550) in a mold compound (e.g., 120) so that a bottom surface (e.g., 525) of the IC chips and conductive elements is exposed.

In some cases, block 1202 includes descriptions for forming packages 500 of FIG. 5. In some cases, block 1202 includes descriptions for forming a strip of portions 511, as described for FIG. 5. In some cases, block 1202 includes, multiple ones of portions 511 formed on a metal carrier, such as by forming a temporary heat activated adhesive on the foil; then placing chips 108 and elements 550 on the foil; etc., as described for FIG. 5. In some cases, block 1202 includes, portions 511 then being debonded from the carrier by adding heat to unbond the adhesive, thus, leaving surface 525 exposed; etc., as described for FIG. 5.

After block 1202 processes 1200 continues to block 1204 where the RDL-stack 502 is generated on (e.g., formed physically directly onto and touching) this exposed front side surface 525.

In some cases, block 1204 includes forming redistribution layers stacks 502 on the exposed bottom surfaces 525 to form a plurality of package devices 500 each having an IC chip 108 and conductive elements 550 on a top surface 525 of each redistribution layers stack 502.

In some cases, block 1204 includes descriptions for forming packages 500 of FIG. 5. In some cases, block 1204 includes descriptions for forming a strip of stacks 502 on portions 511; etc., as described for FIG. 5. In some cases, block 1204 includes, dielectrics 504, traces 506 and traces 540 can be formed onto surface 525; etc., as described for FIG. 5. In some cases, block 1204 includes: applying a first layer of dielectric over surface 525; then forming openings (e.g., etching with a mask) in the first layer of dielectric to surface contacts or areas of chips 108 and elements 550; etc., as described for FIG. 5. In some cases, block 1204 includes applying balls 128 to the packages 510 (e.g., to traces 506 and 540; or to device 500), as described for FIG. 5.

After block 1204 processes 1200 continues to block 1206 where packages 510 (or device 500) are singulated from each other.

In some cases, block 1206 includes singulating the redistribution layers stacks 502 and the conductive elements 550 to form package devices 500 each having a package 510, an IC chip 108, and portions of conductive elements 551 with exposed vertical contact pads 560 at a vertical sidewall 122 where the package was singulated.

In some cases, block 1206 includes, packages 510 (or device 500) being singulated from each other; etc., as described for FIG. 5.

It can be appreciated that embodiments described for FIGS. 1-12 describe various structures or package devices (e.g., devices 100, 100A, 100B, 300A, 300B, 300C, 400, 500, 800, 900 or 1000) for forming or having sidewall conductive elements or contact pads for side-by-side connecting one package having an IC chip to another package.

In some cases, embodiments described for FIGS. 1-12 describe various processes for forming such structures or package devices (e.g., devices 100, 100A, 100B, 300A, 300B, 300C, 400, 500, 800, 900 or 1000) having sidewall conductive elements or contact pads for side-by-side connecting one package having an IC chip to another package.

In some cases, although FIGS. 1-12 may describe solid metal or alloy conductive elements (e.g., elements 150, 250, 450, 550 and the like), the conductive elements may be formed of solder. In these cases it may be challenging to singulate the package devices since during singulation the solder may flow. In addition, the solder may flow in an undefined way when doing a solder connection to the sidewall pads of a second package device (e.g., see FIGS. 6-10).

The embodiments herein provide at least the advantages of more signal (e.g. such as data signal) paths between the chip 108, 108A or 108B and the other packaging device due to the additional contact pads (e.g., 160, etc.) on the side walls provided by the conductive elements (e.g. 150, etc.) and that are in addition to the solder balls at the bottom of the device (e.g. balls 128, etc.). In addition, the conductive elements and sidewall pads can provide a wider (e.g. more vertical cross sectional surface area in directions of height H and length L) and shorter signal path (e.g., in direction of width W) between the package device (or chip 108, 108A or 108B of the device) and a side by side (e.g. horizontally or laterally parallel) other package device having similar side wall pads (e.g., see at least FIGS. 6-7) or otherwise horizontally connected such as through a connector (e.g. see at least FIGS. 8-10) (e.g., as compared to paths through balls 128).

In addition, the embodiments herein provide at least the advantages signal paths from the chip 108, 108A or 108B and through the conductive elements (e.g. 150, etc.) to the other device, that have a reduced parasitic inductance (e.g., as compared to paths through balls 128). Moreover, the embodiments can reduce the number of layers (e.g. of dielectric, vias, and contacts, and traces) in a PCB that are required to interface the signals between the ship or package device and the PCB, by allowing some of the signals to be transmitted through the conductive elements, thus reducing the number of solder bumps 128 and interfaces at the bottom of the device and top of the PCB (e.g., see at least FIGS. 6-7) (e.g., as compared to paths only through balls 128).

In some cases these advantages of the embodiments can be applied to wearable devices, wearable electronics, or other devices where a three-dimensional design or configuration of other package devices to one or more of the package devices herein is desired (see at least FIGS. 6A-10). In some cases, the embodiments can be detected by optical inspection or a cross-section of a device having such a package device with an array or row of sidewall contact pads for connecting to another package device.

As noted above, in some cases, the integrated circuit (IC) chip package devices herein (e.g., devices 100, 100A, 100B, 300A, 300B, 300C, 400, 500, 800, 900 or 1000; and processes for forming structures thereof) may be described as a “package devices having a ball grid array with side wall contact pads” or a “system having package devices having a ball grid array with side wall contact pads” (e.g., devices, systems and processes for forming).

In some cases, package devices or systems having a ball grid array with side wall contact pads may increase in the stability and cleanliness of high frequency transmit and receive data signals transmitted between the data signal circuits of a chip on the package device and another package device (or another chips communicating though the other package device)(e.g., as compared to a data signal transmitting and/or receiving without the package devices or systems having a ball grid array with side wall contact pads). Such an increased frequency may include data signals having a frequency of between 1 and 20 gigatransfers per second (GT/s). In some cases, GT/s may refer to a number of operations (e.g., transmission of digital data such as the data signal herein) transferring data that occur in each second in some given data transfer channel such as a channel provided by the on-die inductor structures; or may refer to a sample rate, i.e. the number of data samples captured per second, each sample normally occurring at the clock edge. 1 GT/s is 10⁹ or one billion transfers per second. In some cases, the on-die interconnection features improves (e.g., reduce) crosstalk (e.g., as compared to a data signal transmitting and/or receiving chip without the on-die interconnection features) from very low frequency transfer such as from 50 mega hertz (MHz) to a GHz transfer level, such as greater than 40 GHz (or up to between 40 and 50 GHz).

In some cases, embodiments of processes for forming the package devices or systems having a ball grid array with side wall contact pads provide the benefits embodied in computer system architecture features and interfaces made in high volumes. In some cases, embodiments of such processes and devices provide all the benefits of solving very high frequency data transfer interconnect problems, such as between two IC chips or die (e.g., where hundreds even thousands of signals between two die need to be routed). In some cases, embodiments of such processes and devices provide the demanded lower cost high frequency data transfer interconnects solution that is needed across the above segments. These benefits may be due to the addition of the package devices or systems having a ball grid array with side wall contact pads which increase performance and speed of the data transfer.

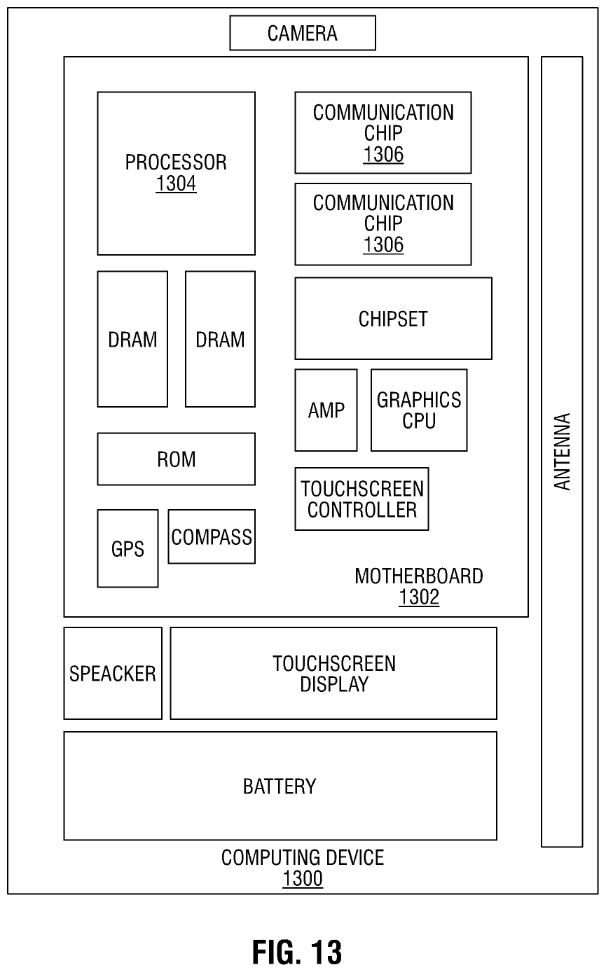

FIG. 13 illustrates a computing device in accordance with one implementation. FIG. 13 illustrates computing device 1300 in accordance with one implementation. Computing device 1300 houses board 1302. Board 1302 may include a number of components, including but not limited to processor 1304 and at least one communication chip 1306. Processor 1304 is physically and electrically coupled to board 1302. In some implementations at least one communication chip 1306 is also physically and electrically coupled to board 1302. In further implementations, communication chip 1306 is part of processor 1304.

Depending on its applications, computing device 1300 may include other components that may or may not be physically and electrically coupled to board 1302. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 1306 enables wireless communications for the transfer of data to and from computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 1306 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 1300 may include a plurality of communication chips 1306. For instance, first communication chip 1306 may be dedicated to shorter range wireless communications such as Wi-Fi and Bluetooth and second communication chip 1306 may be dedicated to longer range wireless communications such as GPS, EDGE, GPRS, CDMA, WiMAX, LTE, Ev-DO, and others.

Processor 1304 of computing device 1300 includes an integrated circuit die packaged within processor 1304. In some implementations, the integrated circuit die of the processor includes one or more devices, such as transistors or metal interconnects. In some embodiments, the package of the integrated circuit die or processor 1304 includes embodiments of processes for forming package devices or systems having a ball grid array with side wall contact pads or embodiments of package devices or systems having a ball grid array with side wall contact pads as described herein. The term “processor” may refer to any device or portion of a device that processes electronic data from registers and/or memory to transform that electronic data into other electronic data that may be stored in registers and/or memory.

Communication chip 1306 also includes an integrated circuit die packaged within communication chip 1306. In accordance with another implementation, the integrated circuit die of the communication chip includes one or more devices, such as transistors or metal interconnects. In some embodiments, the package of the integrated circuit die or chip 1306 includes embodiments of processes for forming package devices or systems having a ball grid array with side wall contact pads or embodiments of package devices or systems having a ball grid array with side wall contact pads as described herein.

In further implementations, another component housed within computing device 1300 may contain an integrated circuit die that includes one or more devices, such as transistors or metal interconnects. In some embodiments, the package of the other integrated circuit die or chip includes embodiments of processes for forming package devices or systems having a ball grid array with side wall contact pads or embodiments of package devices or systems having a ball grid array with side wall contact pads as described herein.

In various implementations, computing device 1300 may be a laptop, a netbook, a notebook, an ultra book, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 1300 may be any other electronic device that processes data.

### EXAMPLES

The following examples pertain to embodiments.

Example 1 is a package device comprising: a package having a substrate with a top surface; a chip mounted on the top surface of the substrate; a mold compound embedding the chip and formed onto the top surface of the package; a plurality of conductive elements mounted on the top surface of the substrate, the conductive elements horizontally disposed at a first vertical sidewall of the package device and having vertical contact pads exposed at the first vertical sidewall; and a plurality of conductor material traces electrically coupling bottom surface contacts of the chip to the plurality of conductive elements.

In Example 2, the subject matter of Example 1 can optionally include further comprising: a first bottom surface with first bottom surface contacts; and conductive traces and vias electrically coupling bottom surface contacts of the chip to the first bottom surface contacts; a plurality of conductor material bumps physically attaching and electrically coupling bottom surface contacts of the chip to the plurality of conductor material traces; and the mold compound formed over and around sides of the chip; over and around one side of the conductive elements; and onto the top surface of the package.

In Example 3, the subject matter of Example 1 can optionally include further comprising the conductive elements mounted on the traces with solder; and the mold compound embedding the conductive elements.

In Example 4, the subject matter of Example 1 can optionally include wherein the conductive elements have one of a half spherical shape, a half wirebond shape, a cube shape, or a cuboid shape; and wherein the conductive elements have a flat surface at the first vertical sidewall.

In Example 5, the subject matter of Example 4 can optionally include wherein the conductive elements are half wirebond shapes, and pairs of the half wirebond shapes have middle portions that vertically cross over each other.

In Example 6, the subject matter of Example 1 can optionally include wherein the substrate includes one of a laminate or a redistribution layers (RDL) stack.

In Example 7, the subject matter of Example 1 can optionally include, further comprising a coating on the exposed surface of the conductive elements.

In Example 8, the subject matter of Example 1 can optionally include wherein the package substrate is a first package substrate, the conductive elements are first conductive elements, and the vertical contact pads are first vertical contact pads; and further comprising a second package device comprising: a plurality of second conductive elements mounted on a second top surface of a second substrate, the second conductive elements horizontally disposed at a second vertical sidewall of the second package device opposite the first vertical sidewall, the second conductive elements having second vertical contact pads exposed at the second vertical sidewall; a plurality of second conductor material traces electrically coupling second bottom surface contacts of a second chip to the second plurality of conductive elements; and solder between, physically attaching and electrically coupling the first vertical contact pads to the second vertical contact pads.

In Example 9, the subject matter of Example 8 can optionally include, further comprising: the first package device having a first bottom surface with first bottom surface contacts; the second package device having a second bottom surface with second bottom surface contacts; a printed circuit board having a top surface with top surface contacts; and solder balls physically attaching and electrically coupling the top surface contacts to the first and second bottom surface contacts.

In Example 10, the subject matter of Example 1 can optionally include a 3-dimensional (3D) molded interconnect device (MID) having: a plurality of 3D MID vertical surface contacts horizontally disposed at a second vertical sidewall of the 3D MID opposite the first vertical sidewall, the vertical surface contacts exposed at the second vertical sidewall; and solder between, physically attaching and electrically coupling the first vertical contact pads to the vertical surface contacts.

In Example 11, the subject matter of Example 10 can optionally include, further comprising: the first package device having a first bottom surface with first bottom surface contacts; a printed circuit board having a top surface with top surface contacts; and solder balls physically attaching and electrically coupling the top surface contacts to the first bottom surface contacts.

In Example 12, the subject matter of Example 10 can optionally include, further comprising a second and third package device having second and third vertical contact pads horizontally disposed at the second vertical sidewall; the 3D MID having second and third vertical surface contacts; the second package device mounted with adhesive on the first package device; the third package device mounted with adhesive on the second package device; solder between, physically attaching and electrically coupling the second vertical contact pads to the second vertical surface contacts; and solder between, physically attaching and electrically coupling the third vertical contact pads to the third vertical surface contacts.

In Example 13, the subject matter of Example 1 can optionally include wherein a connector having spring loaded contact pins; wherein the contact pins are physically attached to and electrically coupled to the vertical contact pads; the first package device having a first bottom surface with first bottom surface contacts; a printed circuit board having a top surface with top surface contacts; and solder balls physically attaching and electrically coupling the top surface contacts to the first bottom surface contacts.

In Example 14, the subject matter of Example 1 can optionally include further comprising a connector having contact tips on ends of flat springs; wherein the contact tips are physically attached to and electrically coupled to the vertical contact pads; wherein the plurality of conductive elements are a first plurality of conductive elements, and the vertical contact pads are first vertical contact pads; and wherein the package device further comprises: a second plurality of conductive elements mounted on the top surface of the substrate, the second conductive elements horizontally disposed at a second vertical sidewall of the package device at an end of the package device that is opposite the first sidewall, the second conductive elements having second vertical contact pads exposed at the second vertical sidewall; and a plurality of conductor material traces electrically coupling bottom surface contacts of the chip to the second plurality of conductive elements.

In Example 15, the subject matter of Example 14 can optionally include, further comprising: the first package device having a first bottom surface with first bottom surface contacts; a printed circuit board having a top surface with top surface contacts; and solder balls physically attaching and electrically coupling the top surface contacts to the first bottom surface contacts.

In Example 16, the subject matter of Example 14 can optionally include wherein the first vertical sidewall and the second vertical sidewall are beveled inwards from a top surface of the package device towards the first bottom surface.

Example 17 is a system comprising: a first package device having: a first package having a first substrate with a first top surface; a first chip mounted on the first top surface of the first substrate; a first mold compound embedding the first chip and formed onto the first top surface of the package; a first plurality of conductive elements mounted on the first top surface of the first substrate, the first conductive elements horizontally disposed at a first vertical sidewall of the first package device and having first vertical contact pads exposed at the first vertical sidewall; and a plurality of first conductor material traces electrically coupling first bottom surface contacts of the first chip to the plurality of first conductive elements; a second package device comprising: a plurality of second conductive elements mounted on a second top surface of a second substrate, the second conductive elements horizontally disposed at a second vertical sidewall of the second package device opposite the first vertical sidewall, the second conductive elements having second vertical contact pads exposed at the second vertical sidewall; a plurality of second conductor material traces electrically coupling second bottom surface contacts of a second chip mounted on the second top surface to the plurality of second conductive elements; and solder between, physically attaching and electrically coupling the first vertical contact pads to the second vertical contact pads.

In Example 18, the subject matter of Example 17 can optionally include, further comprising: the first package device having a first bottom surface with first bottom surface contacts; the second package device having a second bottom surface with second bottom surface contacts; a printed circuit board having a top surface with top surface contacts; and solder balls physically attaching and electrically coupling the top surface contacts to the first and second bottom surface contacts.

Example 19 is a method of forming a package device comprising: obtaining packages including multiple integrated circuit (IC) chip packages each having an IC chip and conductive elements mounted on a top surface of each chip package; embedding the IC chips and conductive elements in a mold compound, the mold compound formed on the top surface of the packages; and singulating the packages through the conductive elements to form package devices each having a package, an IC chip, and portions of conductive elements with exposed vertical contact pads at a vertical sidewall where the package was singulated. In Example 20, the subject matter of Example 19 can optionally include, further comprising: physically attaching and electrically coupling by soldering the vertical contact pads to vertical contact pads or surface contacts of another device.

In Example 21, the subject matter of Example 19 can optionally include wherein the first package device has a first bottom surface with first bottom surface contacts, and further comprising: physically attaching and electrically coupling solder balls to top surface contacts of a printed circuit board and to the first bottom surface contacts.

Example 22 is a method of forming a package device comprising: embedding IC chips and conductive elements in a mold compound so that a bottom surface of the IC chips and conductive elements is exposed; forming redistribution layers stacks on the exposed bottom surfaces to form a plurality of package devices each having an IC chip 108 and conductive elements on a top surface of each redistribution layers stack; and singulating the redistribution layers stacks, the conductive elements and the mold compound to form package devices each having a package, an IC chip, and portions of conductive elements with exposed vertical contact pads at a vertical sidewall where the package was singulated.

In Example 23, the subject matter of Example 22 can optionally include further comprising: physically attaching and electrically coupling by soldering the vertical contact pads to vertical contact pads or surface contacts of another device.

In Example 24, the subject matter of Example 22 can optionally include wherein the first package device has a first bottom surface with first bottom surface contacts, and further comprising: physically attaching and electrically coupling solder balls to top surface contacts of a printed circuit board and to the first bottom surface contacts.

In Example 25, the subject matter can optionally include an apparatus comprising means for performing the method of any one of claims 19-24.

In some cases, the description herein of “top”, “bottom”, “horizontal”, “vertical”, “upper”, “lower”, “side”, “sidewall” and the like are used in a relative sense such that a “top” surface could become a “sidewall” surface and a “sidewall” could become a “bottom” or a “top” surface after rotation (e.g., 90 degrees). Similar relative use may include a “top” surface becoming a “bottom” surface and one “sidewall” becoming an opposing “sidewall” after a rotation (e.g., by 180 degrees). Thus, it can be appreciated that the use of these terms herein is illustrative and can be adapted for and applied to other orientations of the devices, packages, chips, etc. described herein. For example, in some such cases, the “top” and “bottom” surfaces will retain an opposing and parallel surface orientation; the “top” and “sidewall” surfaces will retain a perpendicular surface orientation; and the “horizontal” and “vertical” surfaces will retain a perpendicular surface orientation.

The above description of illustrated implementations, including what is described in the Abstract, is not intended to be exhaustive or to limit embodiments to the precise forms disclosed. While specific implementations of, and examples for, embodiments are described herein for illustrative purposes, various equivalent modifications are possible within the scope, as those skilled in the relevant art will recognize. These modifications may be made to the embodiments in light of the above detailed description. For example, although some embodiments described above show only package devices or systems having a ball grid array with side wall contact pads using the sidewall pads to communicate horizontally with one other package device (e.g., see FIGS. 7-8), those descriptions can apply to forming or having those same package devices or systems having a ball grid array with side wall contact pads for configurations where a first chips is communicating horizontally with a second package at one sidewall 122 and a third package device at a second sidewall 122′ (e.g., where the connector pins or contact tips of FIGS. 9-10 are replaced with solder connections to vertical contact pads of another such package device as shown in FIG. 6B). The terms used in the following claims should not be construed to limit embodiments of the embodiments to the specific implementations disclosed in the specification and the claims. Rather, the scope is to be determined entirely by the following claims, which are to be construed in accordance with established doctrines of claim interpretation.

1. A package device comprising:
a package having a substrate with a top surface;
a chip mounted on the top surface of the substrate;
a mold compound embedding the chip and formed onto the top surface of the package;
a plurality of conductive elements mounted on the top surface of the substrate, the conductive elements horizontally disposed at a first vertical sidewall of the package device and having vertical contact pads exposed at the first vertical sidewall; and
a plurality of conductor material traces electrically coupling bottom surface contacts of the chip to the plurality of conductive elements.

2. The package device of claim 1 further comprising:
a first bottom surface with first bottom surface contacts; and
conductive traces and vias electrically coupling bottom surface contacts of the chip to the first bottom surface contacts;
a plurality of conductor material bumps physically attaching and electrically coupling bottom surface contacts of the chip to the plurality of conductor material traces; and
the mold compound formed over and around sides of the chip; over and around one side of the conductive elements; and onto the top surface of the package.

3. The package device of claim 1 further comprising the conductive elements mounted on the traces with solder; and the mold compound embedding the conductive elements.

4. The package device of claim 1 wherein the conductive elements have one of a half spherical shape, a half wirebond shape, a cube shape, or a cuboid shape; and wherein the conductive elements have a flat surface at the first vertical sidewall.

5. The package device of claim 4 wherein the conductive elements are half wirebond shapes, and pairs of the half wirebond shapes have middle portions that vertically cross over each other.

6. The package device of claim 1 wherein the substrate includes one of a laminate or a redistribution layers (RDL) stack.

7. The package device of claim 1 further comprising a coating on the exposed surface of the conductive elements.

8. The package device of claim 1 wherein the package substrate is a first package substrate, the conductive elements are first conductive elements, and the vertical contact pads are first vertical contact pads; and
further comprising a second package device comprising:
a plurality of second conductive elements mounted on a second top surface of a second substrate, the second conductive elements horizontally disposed at a second vertical sidewall of the second package device opposite the first vertical sidewall, the second conductive elements having second vertical contact pads exposed at the second vertical sidewall;
a plurality of second conductor material traces electrically coupling second bottom surface contacts of a second chip to the second plurality of conductive elements; and
solder between, physically attaching and electrically coupling the first vertical contact pads to the second vertical contact pads.

9. The package device of claim 8 further comprising:
the first package device having a first bottom surface with first bottom surface contacts;
the second package device having a second bottom surface with second bottom surface contacts;
a printed circuit board having a top surface with top surface contacts; and
solder balls physically attaching and electrically coupling the top surface contacts to the first and second bottom surface contacts.

10. The package device of claim 1 further comprising a 3-dimensional (3D) molded interconnect device (MID) having:
a plurality of 3D MID vertical surface contacts horizontally disposed at a second vertical sidewall of the 3D MID opposite the first vertical sidewall, the vertical surface contacts exposed at the second vertical sidewall; and
solder between, physically attaching and electrically coupling the first vertical contact pads to the vertical surface contacts.

11. The package device of claim 10, further comprising:
the first package device having a first bottom surface with first bottom surface contacts;
a printed circuit board having a top surface with top surface contacts; and
solder balls physically attaching and electrically coupling the top surface contacts to the first bottom surface contacts.

12. The package device of claim 10 further comprising a second and third package device having second and third vertical contact pads horizontally disposed at the second vertical sidewall;
the 3D MID having second and third vertical surface contacts;
the second package device mounted with adhesive on the first package device;
the third package device mounted with adhesive on the second package device;
solder between, physically attaching and electrically coupling the second vertical contact pads to the second vertical surface contacts; and
solder between, physically attaching and electrically coupling the third vertical contact pads to the third vertical surface contacts.

13. The package device of claim 1 further comprising a connector having spring loaded contact pins; wherein the contact pins are physically attached to and electrically coupled to the vertical contact pads;
the first package device having a first bottom surface with first bottom surface contacts;
a printed circuit board having a top surface with top surface contacts; and
solder balls physically attaching and electrically coupling the top surface contacts to the first bottom surface contacts.

14. The package device of claim 1 further comprising a connector having contact tips on ends of flat springs; wherein the contact tips are physically attached to and electrically coupled to the vertical contact pads;
wherein the plurality of conductive elements are a first plurality of conductive elements, and the vertical contact pads are first vertical contact pads; and wherein the package device further comprises:
a second plurality of conductive elements mounted on the top surface of the substrate, the second conductive elements horizontally disposed at a second vertical sidewall of the package device at an end of the package device that is opposite the first sidewall, the second conductive elements having second vertical contact pads exposed at the second vertical sidewall; and
a plurality of conductor material traces electrically coupling bottom surface contacts of the chip to the second plurality of conductive elements.

15. The package device of claim 14, further comprising:
the first package device having a first bottom surface with first bottom surface contacts;
a printed circuit board having a top surface with top surface contacts; and
solder balls physically attaching and electrically coupling the top surface contacts to the first bottom surface contacts.

16. The package device of claim 14, wherein the first vertical sidewall and the second vertical sidewall are beveled inwards from a top surface of the package device towards the first bottom surface.

17. A system comprising:
a first package device having:
a first package having a first substrate with a first top surface;
a first chip mounted on the first top surface of the first substrate;
a first mold compound embedding the first chip and formed onto the first top surface of the package;
a first plurality of conductive elements mounted on the first top surface of the first substrate, the first conductive elements horizontally disposed at a first vertical sidewall of the first package device and having first vertical contact pads exposed at the first vertical sidewall; and
a plurality of first conductor material traces electrically coupling first bottom surface contacts of the first chip to the plurality of first conductive elements;
a second package device comprising:
a plurality of second conductive elements mounted on a second top surface of a second substrate, the second conductive elements horizontally disposed at a second vertical sidewall of the second package device opposite the first vertical sidewall, the second conductive elements having second vertical contact pads exposed at the second vertical sidewall;
a plurality of second conductor material traces electrically coupling second bottom surface contacts of a second chip mounted on the second top surface to the plurality of second conductive elements; and
solder between, physically attaching and electrically coupling the first vertical contact pads to the second vertical contact pads.

18. The system of claim 17 further comprising:
the first package device having a first bottom surface with first bottom surface contacts;
the second package device having a second bottom surface with second bottom surface contacts;
a printed circuit board having a top surface with top surface contacts; and
solder balls physically attaching and electrically coupling the top surface contacts to the first and second bottom surface contacts.

19. A method of forming a package device comprising:
obtaining packages including multiple integrated circuit (IC) chip packages each having an IC chip and conductive elements mounted on a top surface of each chip package;
embedding the IC chips and conductive elements in a mold compound, the mold compound formed on the top surface of the packages; and
singulating the packages through the conductive elements to form package devices each having a package, an IC chip, and portions of conductive elements with exposed vertical contact pads at a vertical sidewall where the package was singulated.

20. The method of claim 19 further comprising:
physically attaching and electrically coupling by soldering the vertical contact pads to vertical contact pads or surface contacts of another device.

21. The method of claim 19 wherein the first package device has a first bottom surface with first bottom surface contacts, and further comprising:
physically attaching and electrically coupling solder balls to top surface contacts of a printed circuit board and to the first bottom surface contacts.

22. A method of forming a package device comprising:
embedding IC chips and conductive elements in a mold compound so that a bottom surface of the IC chips and conductive elements is exposed;
forming redistribution layers stacks on the exposed bottom surfaces to form a plurality of package devices each having an IC chip 108 and conductive elements on a top surface of each redistribution layers stack; and
singulating the redistribution layers stacks, the conductive elements and the mold compound to form package devices each having a package, an IC chip, and portions of conductive elements with exposed vertical contact pads at a vertical sidewall where the package was singulated.

23. The method of claim 22 further comprising:
physically attaching and electrically coupling by soldering the vertical contact pads to vertical contact pads or surface contacts of another device.

24. The method of claim 22 wherein the first package device has a first bottom surface with first bottom surface contacts, and further comprising:
physically attaching and electrically coupling solder balls to top surface contacts of a printed circuit board and to the first bottom surface contacts.

25. (canceled)
